(19) United States
(12) Patent Application Publication
(10) Pub. No.: US 2024/0264094 A1
(43) Pub. Date: Aug. 8, 2024

(54) Metasurface for Complex Permittivity Characterization of Dielectric Materials and the Use thereof

(71) Applicant: Georgia Tech Research Corporation, Atlanta, GA (US)

(72) Inventors: Christopher T. Howard, Atlanta, GA (US); Kenneth Wayne Allen, Atlanta, GA (US); William Daniel Hunt, Atlanta, GA (US); David R. Reid, Atlanta, GA (US)

(21) Appl. No.: 18/431,425

(22) Filed: Feb. 2, 2024

Related U.S. Application Data
(60) Provisional application No. 63/482,878, filed on Feb. 2, 2023.

(51) Int. Cl. G01N 22/00; G01R 27/26

(52) U.S. Cl. CPC G01N 22/00; G01R 27/2664; G01R 27/267

(57) ABSTRACT

The exemplary system and method for the characterization procedures for complex permittivity of a dielectric material at radio frequencies, including microwave and millimeter-wave wavelengths. The exemplary system and method employ a highly resonant periodic array affixed or placed in proximity thereto to provide a frequency response that varies based on the constituent electromagnetic properties of a sample of dielectric material.

### CROSS-REFERENCE TO RELATED APPLICATIONS

This application claims priority to and the benefit of U.S. Provisional Application No. 63/482,878, titled “METASURFACE FOR COMPLEX PERMITTIVITY CHARACTERIZATION OF DIELECTRIC MATERIALS AND THE USE THEREOF,” filed on Feb. 2, 2023, the content of which is hereby incorporated by reference herein in its entirety.

### GOVERNMENT LICENSE RIGHTS

This invention was made with Government support under Agreement Number HQ00342190007, awarded by the Government JHTO. The Government has certain rights in the invention.

### SUMMARY

An exemplary system and method are disclosed for the characterization procedures for complex permittivity of a dielectric material at radio frequencies, including microwave and millimeter-wave wavelengths. The exemplary systems and methods employ a highly resonant periodic array to provide a frequency response that varies based on the constituent electromagnetic properties of a sample of dielectric material when affixed or placed in proximity to the material under test.

The exemplary system and method, in some embodiments, employs a two-dimensional metasurface that can be placed against a planar dielectric sample and illuminated with electromagnetic energy. Either transmission and/or reflection are measured. The exemplary system and method can measure the different frequency responses for the unloaded and loaded metasurfaces. The resonance may have a center frequency primarily dependent on the real permittivity of the material under test and a quality (width and depth of the resonance curve) that depends on the imaginary permittivity. Compared to existing techniques for the characterization of complex permittivity, the exemplary system and method can provide a measurement that allows rapid, sensitive characterization with lower costs in both capital expenditure and labor.

The precise characterization of the complex permittivity, particularly loss tangent, in low-loss dielectric samples at microwave frequencies usually employs resonant cavity methods, where the quality factor of some resonance is determined by a precisely dimensioned sample of the material placed inside the cavity. In a study, a hybrid resonance/transmission approach is investigated whereby a highly resonant periodic array attached to a dielectric sample is measured in a broadband-focused beam system. A frequency selective surface (FSS) is designed to be placed against a planar dielectric sample to create a transmission or reflection response that is sensitive to the loss tangent of the material under test. This sandwiched structure is illuminated by the focused beam system to approximate plane-wave-like incidence and scattering parameters measured. It is shown that the magnitude of response at the resonant frequency is linearly dependent on the loss tangent of the material under test for a certain range of loss tangents, and sources of error that limit sensitivity at lower loss tangents are explored.

The exemplary system and method are commercially applicable to those industries that rely heavily on the precise characterization of material permittivity. The aerospace industry is one example of an industry in which electromagnetic properties of materials are important, as materials throughout the aircraft, especially the outer shell, must be or are closely integrated with radio frequency (RF) and infrared (IR) technologies for communication, navigation, and radar purposes. The design of these technologies requires the electromagnetic properties of constituent materials to be known. Material scientists, antenna designers, and systems engineers regularly seek out methods of characterizing the properties of novel materials, including electrical properties, to satisfy various design criteria or as inputs to simulation models.

In addition, there are various applications in the semiconductor industry where in-situ characterization of various dielectric films may be critical to final device performance, such as the SiO2 layer in silicon processing. The use of the instant system and method is also possible in state-of-the-art semiconductor packaging where dielectric consistency of the chip interconnects is necessary to enable operation at effective microwave frequencies.

In some implementations, a method to perform material or device electromagnetic characterization is provided. The method can include: providing a dielectric test material of interest; providing a conductive substrate or elements with a periodic pattern or metasurface in proximity to the dielectric test material to form a test assembly, wherein the conductive substrate or elements are configured to transmit or reflect electromagnetic energy incident upon it with a resonant response with center frequency and resonance shape that varies based on permittivity properties of the dielectric test material; directing electromagnetic energy to the test assembly, wherein the directed electromagnetic energy causes interactions between (i) the periodic pattern or metasurface of the conductive substrate or elements, and (ii) the dielectric test material; capturing an electromagnetic energy profile of the test assembly; and determining an electromagnetic property of the test assembly based on the captured electromagnetic energy profile, wherein the electromagnetic property of the test assembly is used as a characterization of the dielectric test material.

In some implementations, the conductive substrate or elements are formed on a carrier dielectric substrate that is attached to the dielectric test material to form the test assembly.

In some implementations, the conductive substrate or elements include an active electronic circuitry that is placed upon or embedded in a layer of the conductive substrate or elements, and electronic vias are formed between the active electronic circuitry and the conductive substrate or elements.

In some implementations, the active electronic circuitry is configured to adjust resonant properties of the conductive substrate or elements.

In some implementations, the electromagnetic energy is directed by an antenna, a focused beam, a coaxial airline, a waveguide, or a combination thereof.

In some implementations, the conductive substrate or elements include the periodic pattern, and a periodicity between elements in the periodic pattern is between 50% and 80% of a wavelength at the resonant frequency of an interrogation signal corresponding to the directed electromagnetic energy.

In some implementations, the method further includes: evacuating air between the dielectric test material and the conductive substrate or elements.

In some implementations, the method further includes: providing a second conductive substrate or elements with a second periodic pattern or metasurface in proximity to the dielectric test material to form a second test assembly; directing electromagnetic energy to the second test assembly, wherein the directed electromagnetic energy causes interactions between (i) the second periodic pattern or metasurface of the conductive substrate or elements, and (ii) the dielectric test material; and capturing a second electromagnetic energy profile of the second test assembly, wherein the captured second electromagnetic energy profile, or a parameter derived therefrom, of the second test assembly is used as another characterization of the dielectric test material.

In some implementations, a system is provided. The system can include: a test assembly including a conductive periodic pattern or metasurface and a dielectric test material, wherein the conductive substrate or elements are placed in contact with or in proximity to the dielectric test material, and wherein the conductive substrate or elements are configured to transmit or reflect electromagnetic energy incident upon it with a resonant response with center frequency and resonance shape that varies based on permittivity properties of the dielectric test material; an antenna configured to capture an electromagnetic energy profile of the test assembly in response to electromagnetic energy directed to the test assembly, wherein the directed electromagnetic energy causes interactions between (i) the periodic pattern or metasurface of the conductive substrate or elements, and (ii) the dielectric test material; and an analyzer configured to measure and determine an electromagnetic property of the test assembly based on the captured electromagnetic energy profile, wherein the electromagnetic property of the test assembly is used as a characterization of the dielectric test material.

In some implementations, the analyzer is further configured to: determine dielectric constant and loss tangent of the dielectric test material.

In some implementations, the conductive substrate or elements are formed on a dielectric substrate that is attached to the dielectric test material to form the test assembly.

In some implementations, the test assembly includes active electronic circuitry that is placed upon or embedded in a layer of the dielectric substrate, and electronic vias are formed between the active electronic circuitry and the conductive substrate or elements.

In some implementations, the active electronic circuitry is configured to adjust resonant properties of the conductive substrate or elements.

In some implementations, the system further includes an energy generator configured to generate and/or direct the electromagnetic energy.

In some implementations, the energy generator includes a microwave source, power meters, network analyzer, antennas, focusing lenses or reflectors, a coaxial airline, a waveguide, or a combination thereof.

In some implementations, the conductive substrate or elements include the periodic pattern, and a periodicity between elements in the periodic pattern is between 50% and 80% of a wavelength at the resonant frequency of an interrogation signal corresponding to the directed electromagnetic energy.

In some implementations, the system is configured as a broadband-focused beam system.

In some implementations, the test assembly is mounted on a fixture.

In some implementations, the test assembly is mounted on a vacuumed fixture including vacuum channels, fittings, and integrated seals.

In some implementations, a non-transitory computer readable medium is provided. The non-transitory computer readable medium can include a memory having instructions stored thereon to cause a processor to: analyze an electromagnetic energy profile acquired via a test assembly in response to electromagnetic energy directed thereto, wherein the test assembly includes: (i) a conductive layer with a periodic pattern or metasurface, and (ii) a dielectric test material, wherein the conductive layer is in contact with or positioned in proximity to the dielectric test material, wherein the conductive layer is configured to transmit or reflect electromagnetic energy incident upon it with a resonant response with center frequency and resonance shape that varies based on permittivity properties of the dielectric test material, and wherein the directed electromagnetic energy causes interactions between (i) the periodic pattern or metasurface of the conductive layer, and (ii) the dielectric test material.

Other systems, methods, and/or features will be or may become apparent to one with skill in the art upon examination of the following drawings and detailed description. It is intended that all such additional system, methods and/or features be included with this description and be protected by the accompanying claims.

### BRIEF DESCRIPTION OF THE FIGURES

The components in the drawings are not necessarily to scale relative to each other. Like reference, numerals designate corresponding parts throughout the several views.

FIG. 1 is an example free space-focused beam system configured for microwave and millimeter-wave wavelength complex permittivity characterization of a test assembly comprising a dielectric test material coupled with a resonant periodic array in accordance with an illustrative embodiment.

FIG. 2 is a flowchart illustrating a method in accordance with certain embodiments of the present disclosure.

FIG. 3A and FIG. 3B depict example materials under test in accordance with embodiments of the present disclosure.

FIGS. 3C-3I show example frequency selective surfaces (FSS), i.e., metasurfaces in accordance with embodiments of the present disclosure.

FIG. 4 shows an example test assembly that includes a vacuum pump in accordance with embodiments of the present disclosure.

FIG. 5A shows an example cross FSS in accordance with embodiments of the present disclosure.

FIG. 5B shows a free-space-focused beam system in accordance with the embodiments of the present disclosure.

FIG. 5C is a graph depicting the loading of the FSS with a dielectric substrate in accordance with embodiments of the present disclosure.

FIG. 5D depicts an example setup in accordance with embodiments of the present disclosure.

FIG. 5E shows a comparison of resonance measurements.

FIG. 5F is a schematic diagram illustrating experimental results.

FIG. 5G-5J are graphs showing experimental results from a study that was conducted.

FIG. 6A shows a universal geometry for studying a loss tangent measurement surface (LTMS) in accordance with the embodiments of the present disclosure.

FIG. 6B is a graph showing experimental results from a study that was conducted.

FIG. 6C-6E are schematic diagrams showing details and results from a study that was conducted.

FIG. 6F-6H are graphs showing experimental results from a study that was conducted.

FIG. 7A depicts a resonance in the complex s-plane.

FIG. 7B-7H are graphs showing experimental results from a study that was conducted.

FIG. 7I depicts a suite of metasurfaces in accordance with the embodiments of the present disclosure.

FIG. 8A depicts a finite-difference time-domain (FDTD) model in accordance with embodiments of the present disclosure.

FIG. 8B is a graph showing experimental results from a study that was conducted.

FIG. 8C is a flowchart of a Multi-Objective Genetic Algorithm (MOGA).

FIGS. 8D and 8E are graphs showing experimental results from a study that was conducted.

FIG. 8F demonstrates the localization of distinct resonant regions in the optimized surface pattern.

FIG. 8G is a graph corresponding to FIG. 8F.

FIG. 9A-9G show experimental results from a study that was conducted.

FIG. 10 is an example computing device.

### DETAILED SPECIFICATION

To facilitate an understanding of the principles and features of various embodiments of the present invention, they are explained hereinafter with reference to their implementation in illustrative embodiments.

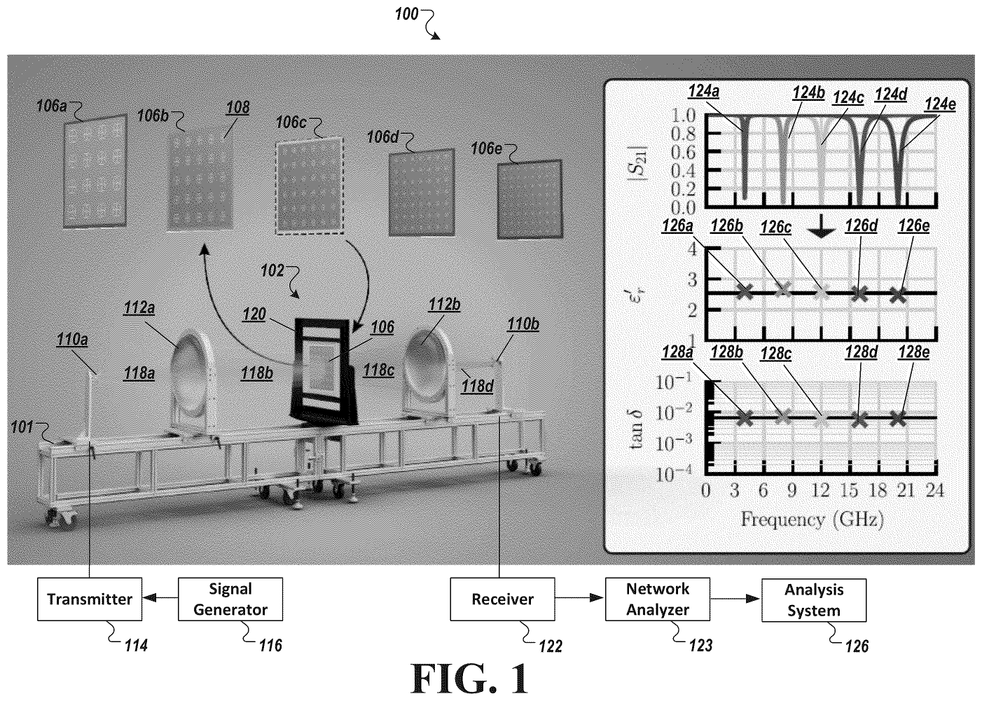

Embodiments of the present disclosure focus on sensing methodologies for metasurfaces. A design methodology for a loss tangent measurement surface (LTMS), a metasurface-based sensor for accurately deriving the dielectric constant and loss tangent that makes up the complex permittivity of planar dielectric samples, as illustrated in FIG. 1. In some implementations, an example system comprises at least a power source or transmitter which can be varied in frequency, and a power meter to measure the resulting power.

### Example System

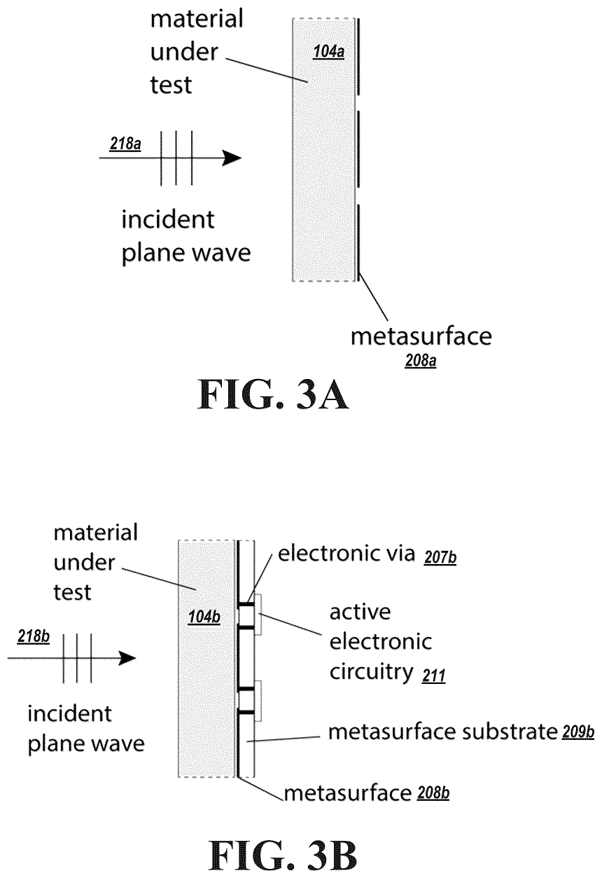

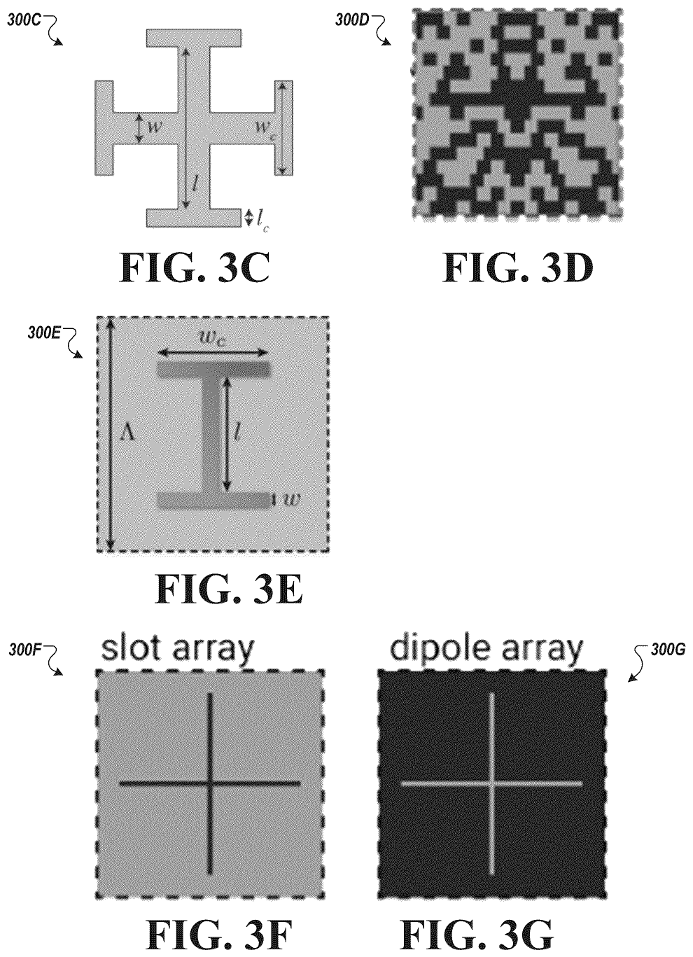

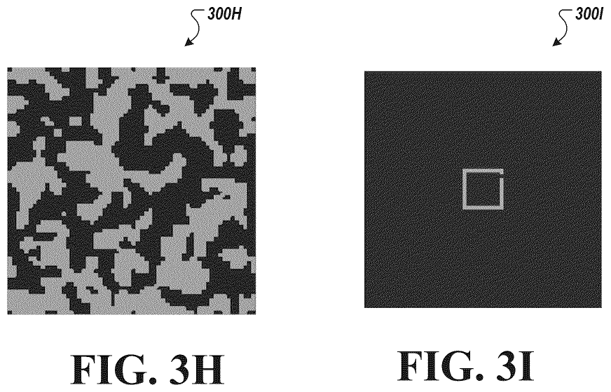

FIG. 1 shows an example free-space focused-beam system 100 configured for microwave and millimeter-wave wavelength complex permittivity characterization of a test assembly 102 comprising a dielectric test material 104 (see, e.g., FIG. 3A and FIG. 3B) coupled with a resonant periodic array 106 comprising conductive elements forming a periodic pattern or metasurface 108 in accordance with an illustrative embodiment.

In the example shown in FIG. 1, the system 100 includes a frame 101 that houses a set of horn antennas 110 (shown as 110a, 110b) with focusing elements 112 (shown as 112a, 112b) to focus the energy onto the test assembly 102. In some implementations, an aperture or array antenna is used as a feed antenna for the system 100 instead of the horn antennas 110. In various implementations, open-boundary horns (quad-ridge and dual-ridge), conical horns, TEM horns, corrugated feeds, open-ended waveguides, or planar apertures can be employed. The system 100 includes a transmitter 114 coupled to a signal generator 116 to generate microwave or millimeter-wave electromagnetic beam 118a at the horn antenna 110a. The generated beam 118a is directed through the focusing element 112a that focuses the electromagnetic beam 118 (shown as 118b) onto the test assembly 102 mounted in a fixture 120. A focus is formed in front of focusing element 112a, and test assembly 102 is situated at the focus where the phase taper is minimized, and the fields can be approximated as plane-wave like. The focusing elements (112a, 112b) can be dielectric lenses (e.g., made of Rexolite) or can be metal parabolic reflectors. The focusing elements 112, for example Rexolite lenses, can functionally confine the incident electromagnetic energy to a narrow spot size to reduce diffraction effects from the edges of the dielectric test material (104). In some embodiments, the focusing elements comprise metallic reflectors of a particular shape (e.g., hyperbolic or parabolic shape) or metamaterial lenses that are configured to focus the energy. Alternatively, any antenna feed which is designed to produce a collimated or focused beam, for example, a dielectric rod antenna or commercial spot-focusing lens antenna, can be employed. In some implementations, the system 100 may not include any focusing elements 112. The electromagnetic beam 118b is directed through the test assembly 102, and the resulting electromagnetic beam 118c is directed to through the second focusing element 112b, which expands the beam 118c. The resulting expanded beam 118d is received at the second horn antenna 110b, which is coupled to a receiver 122 and network analyzer 123 that provides or stores the measurements for analysis. The system 100 can be used provide characterization of the dielectric test material 104 between 2 gigahertz (GHz)-110 GHz, for example, 2 GHz-32 GHz, 4-40 GHz, 60-110 GHz.

Due to challenges associated with obtaining calibrated magnitude and phase information, a vector network analyzer which combines the functions of swept continuous wave (CW) source, magnitude and phase measurement, and the associated algorithms to calculate reflection and transmission in one tool can be employed as the network analyzer. In other implementations, a signal generator, transmitter, and power meter can be employed.

Notably, the test assembly 102 includes the dielectric test material 104 coupled with a resonant periodic array 106 having a periodic pattern or metasurface 108. The resonant periodic array 106 comprises a conductive substrate or elements with a periodic pattern or metasurface 108 configured to transmit or reflect electromagnetic energy incident upon it with a resonant response with center frequency and resonance shape that varies based on permittivity properties of the dielectric test material 104. The directed electromagnetic energy through the test assembly 102 causes interactions between (i) the periodic pattern or metasurface 108 of the conductive substrate or elements, and (ii) the dielectric test material 104.

Different resonant periodic arrays 106 (shown as 106a, 106b, 106c, 106d, 106e, etc.) having different periodic patterns or metasurfaces 108 can be employed to provide different responses for transmission |S₂₁|, permittivity εᵣ′, and loss tangent tan δₘ characterization (shown as 124a-124e, 126a-126e, and 128a-128e, respectively). In the example shown in FIG. 1, five resonant periodic arrays 106a-e are provided. The number of resonant periodic arrays 106 that may be used, includes, but are not limited to, 1, 2, 3, 4, 5, 6, 7, 8, 9, 10, depending on the material and frequency of interest. In some embodiments, more than 10 arrays may be employed. The resonant periodic arrays 106 may have the same pattern 108 for a test. In some embodiments, multiple sets of resonant periodic arrays 106 with different patterns 108 may be employed.

Other antenna configurations may be employed, as described or referenced herein, e.g., a configuration with, but not limited to, one or more focused beam antennas, one or more coaxial airline antennas, one or more waveguides, or a combination thereof

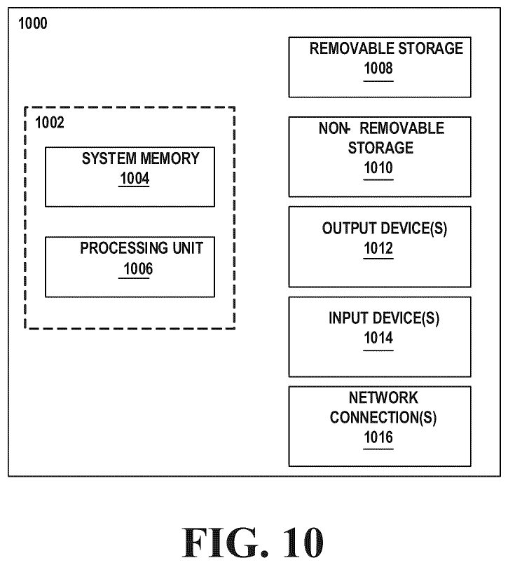

In some implementations, the system 100 is operatively coupled to or includes a processor (e.g., computing device, interface, or the like). This disclosure contemplates that the processor can be the computing device illustrated in FIG. 10. The processor may be configured to receive data/information from the network analyzer 123 and/or the analysis system 126 captured via one or more antennas (e.g., first horn antenna 110a and second horn antenna 110b). For example, the network analyzer 123 can measure a signal magnitude and compute scattering parameters (transmission and reflection), which are then retrieved from the network analyzer 123 by the processor/computing device.

Air gap effect minimization. To reduce the effects of air gaps between the dielectric material-under-test 104 and the resonant periodic array 106, the test assembly 102 may be vacuumed to evacuate air between the material-under-test and the measurement surface substrate. In some embodiments, a tape is then used to seal along the edges of the measurement surface. In some embodiments, the fixture 120 may be configured to house the test assembly 102 and includes vacuum channels and fittings and integrated seals on the edges. Other mechanisms for removing or minimizing air gaps can include utilizing a tape and squeegee, temporary spray adhesive, or mechanical reinforcement.

### Example Method

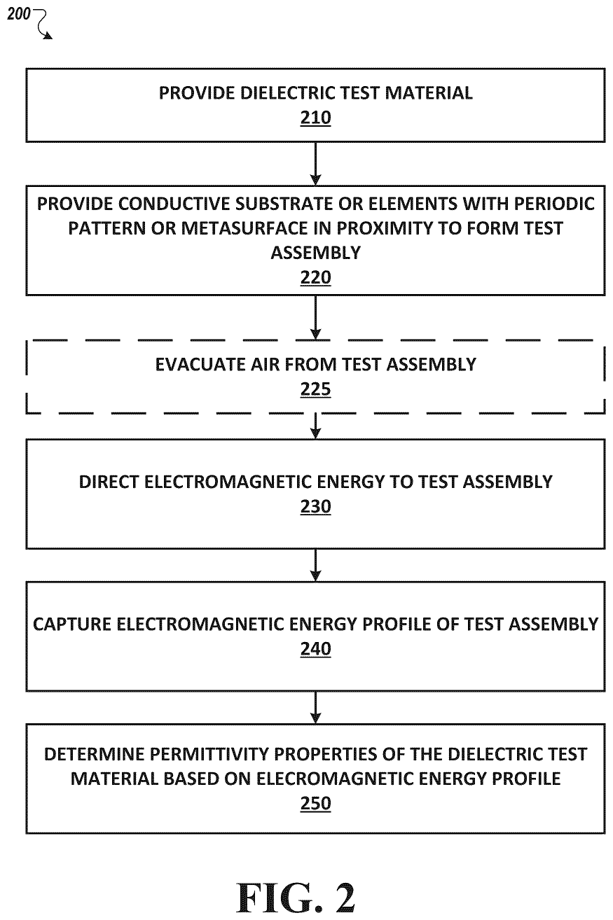

FIG. 2 is a flowchart of an example method 200 for determining permittivity properties of a dielectric test material, for example, in order to determine a dielectric constant and loss tangent of the dielectric test material. In some implementations, the method 200 can be at least partially performed using the system 100 described in connection with FIG. 1. Additionally, and or alternatively, the method 200 can be at least partially performed by a processing circuitry (for example, but not limited to, an application-specific integrated circuit (ASIC), or a central processing unit (CPU)). In some examples, the processing circuitry may be electrically coupled to and/or in electronic communication with other circuitries of an example computing device, such as, but not limited to, the example computing device 1000 described above in connection with FIG. 10. In some examples, embodiments may take the form of a computer program product on a non-transitory computer-readable storage medium storing computer-readable program instruction (e.g., computer software). Any suitable computer-readable storage medium may be utilized, including non-transitory hard disks, CD-ROMs, flash memory, optical storage devices, or magnetic storage devices. This disclosure contemplates that the example operations can be performed using one or more computing devices (e.g., at least the basic configuration illustrated in FIG. 10 by box 1002).

At step 210, the method includes providing a dielectric test material of interest. In some implementations, the dielectric test material comprises a planar test material.

At step 220, the method includes providing a conductive substrate or elements with a periodic pattern or metasurface in proximity to the dielectric test material to form a test assembly. In some implementations, the conductive substrate or elements are formed on a carrier dielectric substrate that is attached to the dielectric test material to form the test assembly.

This disclosure contemplates that the conductive substrate, elements, or metasurface (terms used interchangeably herein) can include any of the FSSs/metasurfaces described in connection with FIGS. 3C-3I below. In some implementations, the conductive substrate or elements comprise a periodic pattern, and a periodicity between elements in the periodic pattern is between 50% and 80% of a wavelength at the resonant frequency of an interrogation signal corresponding to electromagnetic energy directed to the test assembly.

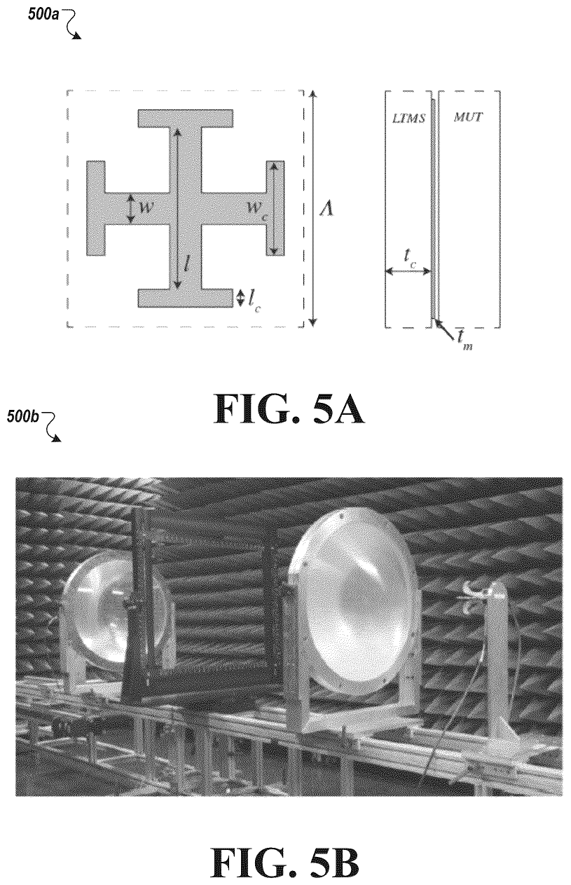

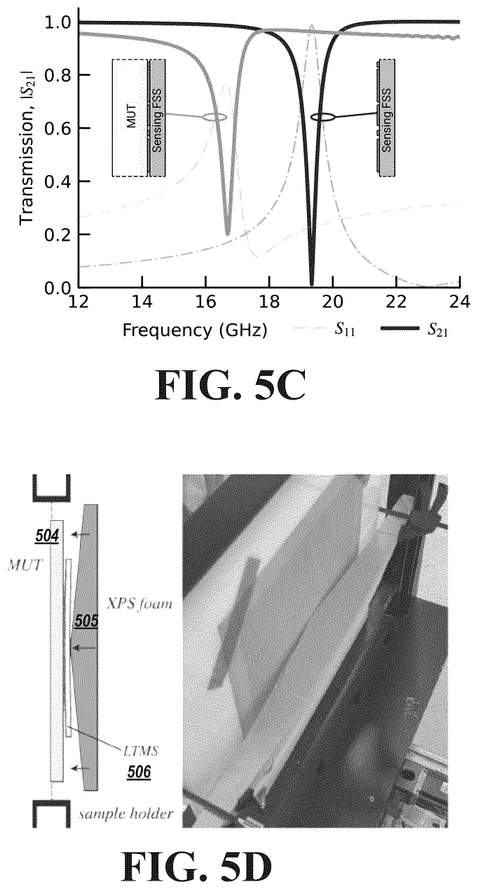

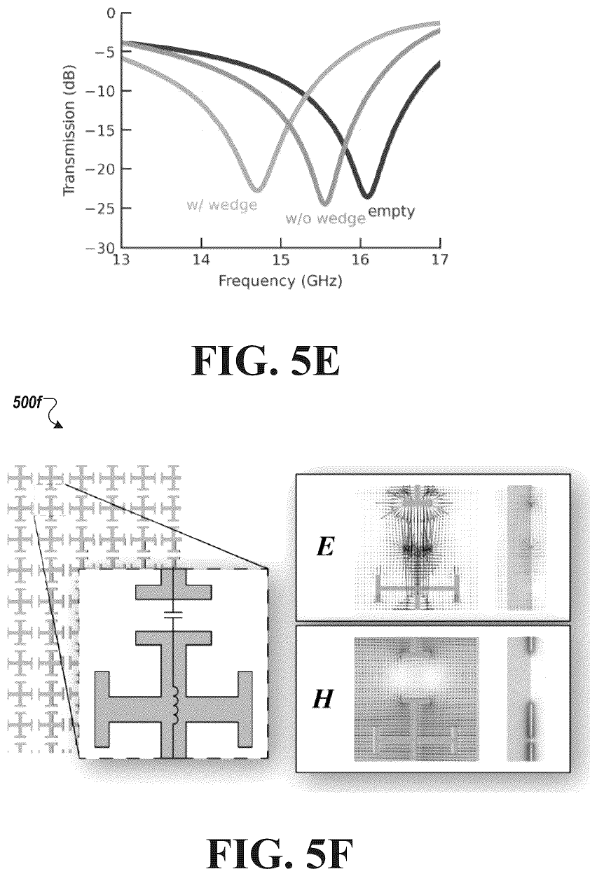

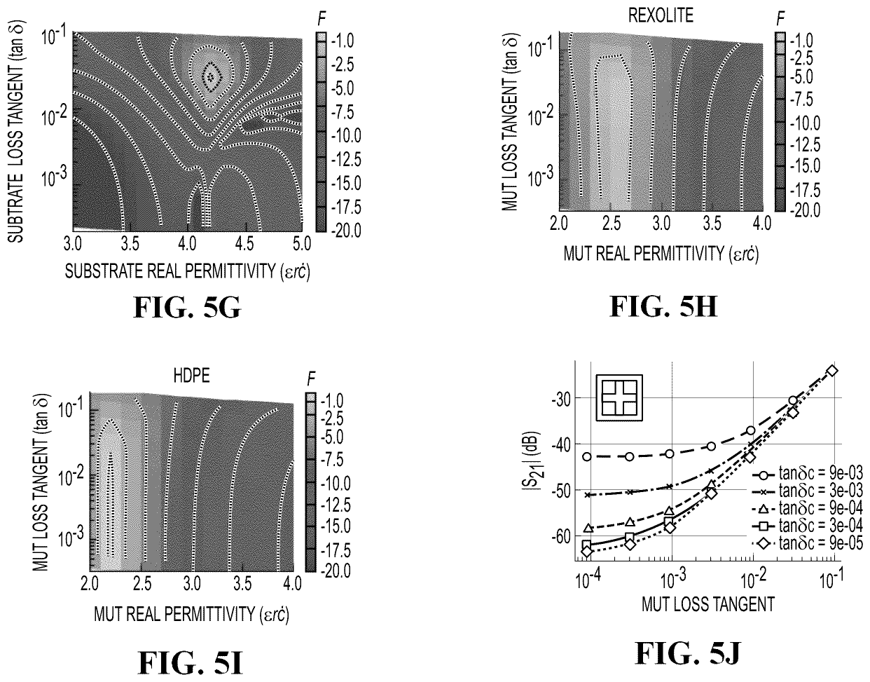

Optionally, at step 225, the method includes evacuating air from the test assembly. In some implementations, a system or test assembly (e.g., test assembly 102) includes components for reducing the effect of air gaps between the dielectric material-under-test and the conductive elements. In some implementations, the method includes using a polystyrene foam wedge (described in connection with FIG. 5D below). In some examples, a vacuum pump is used to evacuate air between the material-under-test and the measurement surface substrate, with tape used to seal along the edges of the measurement surface. In other implementations, a fixture is provided which contains the measurement surface, vacuum channels and fittings, and integrated seals on the edges. Other mechanisms for evacuating air include using tape and squeegee, the use of temporary spray adhesive, or mechanical reinforcement.

At step 230, the method includes directing electromagnetic energy to the test assembly. In some implementations, antennas (e.g., horn antennas) and one or more focusing elements are used to direct/focus the electromagnetic energy onto the test assembly. In some examples, the electromagnetic energy is directed by an antenna, a focused beam, a coaxial airline, a waveguide, an energy generator, or combinations thereof. In some implementations, an active electronic circuitry is used to adjust the resonant properties of the conductive substrate or elements. The active electronic circuitry can be placed upon or embedded in a layer of the conductive substrate or elements. In some examples, electronic vias are formed between the active electronic circuitry and the conductive substrate or elements.

At step 240, the method includes capturing an electromagnetic energy profile of the test assembly. For example, data/information can be captured using a receiver, network analyzer, and/or analysis system.

At step 250, the method includes determining permittivity properties of the dielectric test material based, at least in part, on the electromagnetic energy profile. In some examples, the method includes determining a dielectric constant and loss tangent of the dielectric test material.

Example Test Assembly with Resonant Periodic Array with Periodic Pattern or Metasurface

FIG. 3A shows an example material under test 104a (e.g., dielectric test material) positioned in proximity to a metasurface 208a in accordance with embodiments of the present disclosure. The example metasurface 208a can be a periodic array of thin metallic elements that are configured to exhibit a particular frequency and shape of resonance and may be affected by the real permittivity and loss of neighboring dielectrics. The metasurface 208a can comprise a thin conductive screen, substrate, or layer with a periodic pattern, which transmits or reflects electromagnetic energy 218a incident upon it with a resonant response with center frequency and resonance shape that varies considerably based on the complex permittivity of a dielectric material placed on either side of the metasurface. The center frequency and bandwidth of the resonance in the absence of any nearby dielectrics are determined by the geometry of the metallic pattern comprising the metasurface 208a. From measurements of reflection or transmission in the frequency region where the metasurface resonance occurs, the complex permittivity of the dielectric may be computationally extracted from an observation of the frequency shift and bandwidth change of the resonant response.

While certain metasurface patterns may allow an embodiment to consist solely of a conductive sheet to be placed against a material under test (MUT) 104a, embodiments with metasurface patterns comprise disjoint metallic traces which require fabrication of the metasurface on a carrier dielectric substrate, preferably one with extremely low loss. Doing so has some impact on the sensitivity of the measurement technique but is not destructive to it.

FIG. 3B shows an example embodiment of a material under test 104b positioned in proximity to a metasurface 208b that comprises an active electronic circuitry 211. As noted above, the metasurface 208b transmits or reflects electromagnetic energy 218b incident thereon. In some embodiments, as shown, an active electronic circuitry 211 is placed embedded in or upon the substrate 209b to the metasurface 208b, with electronic vias 207b as necessary to create electrical continuity between the electronics and the metasurface 208b. Digital or analog control of the active electronic circuitry 211 changes the resonant properties of the metasurface 208b, enabling the measurement of many disparate frequencies with a single active metasurface 208b.

Current measurement practice uses one of two classes of techniques: broadband transmission line techniques, including focused beam, coaxial airline, and waveguide measurements, or narrowband resonant techniques, such as resonant cavities, open-boundary Fabry-Perot resonators, and split-cylinder resonators. Broadband methods are certainly capable of characterizing dielectrics over multi-octave bandwidths but lack the parts-per-thousand or better precision often desirable in classifying the imaginary permittivity, or loss, in the material.

Resonant methods can achieve this sensitivity, but usually at a single frequency or narrow range of frequencies; multiple individual measurement fixtures are required to obtain broadband data, potentially at great expense. The exemplary system and method can rely on a narrowband resonant structure, but with several key advantages:

The metasurface itself is comparatively low cost and can create individual metasurfaces for each frequency or band of interest is substantially cheaper than multiple present technologies, for example, precision waveguides.

The measurement of multiple metasurfaces may take substantially less time and labor to set up the measurement fixture and record measurement data as compared to present technologies.

The exemplary system and method are nondestructive to the sample being measured, and a single planar dielectric sample may be used for every individual frequency measurement by swapping out the metasurface, with flexibility for a wide range of sample thicknesses. Current state-of-the-art resonant measurement techniques rely on precisely dimensioned samples of different sizes for each frequency.

### Example Frequency Selective Surface and Metasurfaces

FIGS. 3C-3I show an example periodic patterns or metasurfaces 108 for resonant periodic arrays 106. The periodic patterns or metasurfaces, as a frequency selective surface (FSS), can be placed against or in proximity to a dielectric material to create a transmission or reflection response that is sensitive to the loss tangent of a material under test.

FIG. 3C shows a unit cell of a periodic pattern or metasurface 108 (shown as 300c) comprising a Jerusalem cross-frequency selective metasurface in accordance with certain embodiments described herein. The pattern can be defined parametrically. In addition, the distance between the periodic pattern and the nearby pattern can be defined parametrically.

FIG. 3D shows a unit cell of a periodic pattern or metasurface 108 (shown as 300d) comprising an example tunable metasurface pattern in accordance with certain embodiments described herein. The pattern can be defined parametrically. In addition, the distance between the periodic pattern and the nearby pattern can be defined parametrically.

FIG. 3E shows a unit cell of a periodic pattern or metasurface 108 (shown as 300e) comprising an example “dogbone shaped” cross frequency selective metasurface in accordance with certain embodiments described herein. The pattern can be defined parametrically. In addition, the distance between the periodic pattern and the nearby pattern can be defined parametrically.

FIG. 3F shows a unit cell of a periodic pattern or metasurface 108 (shown as 300f) comprising an example slot array metasurface that can form a high impedance, reactive surface at resonance, in accordance with certain embodiments described herein. The pattern can be defined parametrically. In addition, the distance between the periodic pattern and the nearby pattern can be defined parametrically.

FIG. 3G shows a unit cell of a periodic pattern or metasurface 108 (shown as 300g) comprising an example dipole array metasurface which has zero reactance at resonance such that shunt admittances introduced by neighboring dielectrics have no effect on the resonant frequency, in accordance with certain embodiments described herein. The pattern can be defined parametrically. In addition, the distance between the periodic pattern and the nearby pattern can be defined parametrically. The pattern can be defined parametrically. In addition, the distance between the periodic pattern and the nearby pattern can be defined parametrically.

FIG. 3H shows a unit cell of a periodic pattern or metasurface 108 (shown as 300h) comprising an example level set unit cell metasurface and can be useful for algorithmic optimization of the metastructure. The pattern can be defined parametrically. In addition, the distance between the periodic pattern and the nearby pattern can be defined parametrically. Additional examples of level set unit cell metasurfaces in accordance with the present disclosure are described in Alex Saad-Falcon et al. “Level set methods for gradient-free optimization of metasurface arrays”. https://arxiv.org/pdf/2307.07606.pdf, July 2023, the content of which is hereby incorporated by reference herein in its entirety.

FIG. 3I shows a unit cell of a periodic pattern or metasurface 108 (shown as 300i) comprising an asymmetric split ring resonator. The pattern can be defined parametrically. In addition, the distance between the periodic pattern and the nearby pattern can be defined parametrically.

Additional examples of metasurfaces that can be used in accordance with the present disclosure are described in PCT Application No. WO 2023/033819, entitled “ELECTROMAGNETIC METASTRUCTURES FOR RADOME OR ANTENNAE,” filed Sep. 1, 2021, the content of which is hereby incorporated by reference herein in its entirety.

### Example Air Evacuation Fixture

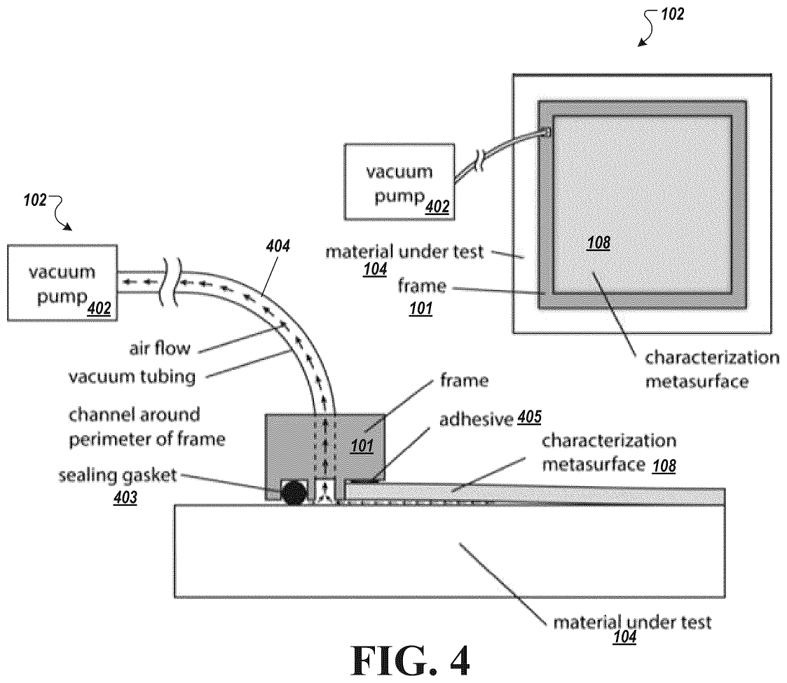

To reduce the effects of air gaps, an example system can include a vacuum fixture. FIG. 4 shows views of a test assembly 102 comprising frame 101 coupled to a characterization metasurface 108 (also referred to herein as a measurement surface substrate) using an adhesive. The characterization metasurface 108 is positioned in proximity to a dielectric material-under-test 104. A vacuum pump 402 is attached to the frame 101 and used to evacuate air between the material-under-test 104 and the characterization metasurface 108. As shown, the vacuum pump 402 is connected to the frame 101 via vacuum tubing 404 and evacuates air from the test assembly 102 through the vacuum tubing 404. Additionally, a channel surrounds the perimeter of the frame 101 and a sealing gasket 403 is used to prevent air penetration.

### Experimental Results and Additional Examples

Studies have been conducted to evaluate the exemplary systems and methods described herein. Various design recommendations for the LTMS are described herein as an exemplary application of permittivity characterization behavior common to this class of sensors. Studies were conducted in which a suite of LTMS sensors were designed for microwave frequencies, constructed, and used to characterize a few low-loss materials.

The exemplary method may be performed using focused beam operations, among others described herein. While the measurement may not need to be performed in an anechoic chamber, doing so could potentially increase measurement performance by a small amount. The focused nature of the focused beam system obviates the need to use an anechoic chamber. Various calibration procedures and signal-processing operations may be performed to remove any reflections occurring from surfaces in the measurement room (well summarized in the Bartley-Begley reference).

### Example #1—Loss Tangent Measurement Surface for Free Space-Focused Beam Characterization of Low-Loss Dielectrics

An existing frequency-selective surface with a cross-bandstop pattern was selected to evaluate the LTMS concept. This surface is a simple single-sided bandstop FSS constructed on a fiberglass-reinforced epoxy substrate, likely FR-4. The provenance of this substrate is unknown and the wide range of substrates of varying permittivity and loss carrying the FR-4 designation forces the complex permittivity of the substrate to be treated as an unknown to be extracted as part of this work. The parameters of the FSS geometry are illustrated in FIG. 5A and the measured dimensions of the FSS are tabulated in Table I below.

TABLE 1

| Dimension | Symbol | Value | |
|---|---|---|---|
| Period | Λ | 250 | mils |
| Length | l | 147.5 | mils |
| Width | w | 10 | mils |
| Capacitor Leg Length | l_{c} | 10 | mils |
| Capacitor Leg Width | w_{c} | 55 | mils |
| Substrate Thickness | t_{c} | 46.25 | mils |
| Metal Thickness | tₘ | 1.2 | mils |

A cross FSS 500a was selected as a proof of concept from a variety of available FSS designs for two reasons: 1) the bandstop response of the FSS design implies a strong resonant null in its transmission, avoiding some of the challenges associated with reflection measurements, and 2) the capacitive “leg” or “hat” of the Jerusalem cross geometry provides an intuitive basis for a resonance shift due to changing permittivity.

Measurement Setup. A free-space-focused beam system 500b, illustrated in FIG. 5B, is used to measure the transmission and reflection response of the FSS and to extract complex permittivity of dielectric samples from microwave measurements. A pair of commercial off-the-shelf (COTS) open boundary quad-ridge horns [13] is used in the measurement setup, enabling characterization over 2-32 GHz for samples approximately 12 to 24 inches per side. In general, focused beam systems are convenient for material characterization due to their broadband nature (4-40 GHz or 60-110 GHz in a single sweep), but as is typical with broadband measurements, their limited precision is unable to precisely characterize small quantities, such as the loss tangent of a low-loss dielectric sample.

To calibrate the measurement system, a Gated Reflect Line (GRL) calibration was used [14]. Two-port scattering parameters are collected for an empty sample holder (maximum response for the transmission case and maximum isolation for the reflection case) and for a metal plate (isolation for transmission and maximum response for reflection) placed at the measurement reference plane.

Measurement data is corrected by subtracting isolation data from both the sample measurement and the maximum response measurement, then dividing sample by response:

$${S}_{m n , ca l} = \frac{{s}_{m n , MUT} - {s}_{m n , iso}}{{s}_{m n , res} - {s}_{m n , iso}} .$$

Further systematic errors are finally removed by time-gating the calibrated data, isolating the response of the material under test (MUT) from mismatches and losses in the focused beam system. A time gate window of 2 nanoseconds (ns) is selected to sufficiently capture the lengthy decay of the transmission response at resonance.

Effect of dielectric loading on frequency response. Two measurements are taken to determine the complex permittivity of a dielectric substrate: the first is a measurement of the FSS alone to capture the unloaded resonance of the FSS, and the second with the FSS pattern sandwiched between the FSS substrate and the material under test to quantify the total resonance shift after loading. These two measurements are shown for a 0.25-inch sample of crosslinked polystyrene in FIG. 5C. FIG. 5C is a graph depicting the loading of the FSS with a dielectric substrate showing that the 0.25″ crosslinked polystyrene shifts the resonant frequency in a transmission measurement.

Air Gap Mitigation. Due to deviations from planarity in a constructed FSS as well as undulations in plating thickness, it is possible that a slight air gap exists when the LTMS is placed against the MUT. This air gap is detrimental to measurement performance; because the LTMS resonance shift is a result of the effective permittivity of the material surrounding the metal pattern, the presence of air in the stackup will greatly decrease the amount of resonance shift from what may be expected.

To mitigate this issue, an extruded polystyrene (XPS) foam wedge with low permittivity was constructed and loosely clamped to the edges of the sample, providing pressure on the center of the FSS to ensure close contact, particularly at the center of the measurement beam, as shown in FIG. 5D. In particular, FIG. 5D depicts an example setup including an MUT 504, XPS foam wedge 505, and LTMS 506. A comparison of resonance measurements with and without the wedge is graphically illustrated in FIG. 5E.

FIG. 5F is a schematic diagram illustrating that loading the FSS 500f

Figure with a dielectric substrate—in this case, 0.25″ crosslinked polystyrene—shifts the resonant frequency in a transmission measurement.

Extraction of Permittivity. The extraction technique for the LTMS relies principally on achieving agreement between the focused beam measurement and a modeled representation of the LTMS. A finite-difference time-domain (FDTD) model is constructed to model the expected frequency response from different values of real permittivity and loss tangent.

Because the substrate of the cross LTMS of FIG. 5A is unknown, the extraction technique must first be used to determine its complex permittivity. An accurate characterization is required, as any errors will be propagated to MUT measurements through the cascade of MUT and LTMS. The geometry described in Table I is constructed on an FDTD grid with a grid spacing of 1.25 mils. A parametric sweep of permittivity and loss tangent is run, with transmission frequency response recorded for each individual simulation. Each simulation is evaluated against a generalized mean cost function per Equation 1.

$$F = {[ \frac{1}{n} {\sum }_{i}^{n} {\vert Δ {S}_{21 , d B} ( {f}_{i} ) \vert}^{P} ]}^{1 / P} \qquad ( Eq . 1 )$$

In Equation 1, ΔS_{21,dB} is the difference between measured and modeled transmission magnitude in dB at each frequency point over the range between 10 and 20 GHz (p=8). The parametric sweep of cost function evaluations is shown in FIG. 5G.

This analysis determines the permittivity of the FR-4 substrate to be ∈ᵣ=4.2 with a loss tangent tan=0.027. The model is then updated with this permittivity value, and a second parametric sweep is performed for varying complex permittivities of the material under test. A small air gap (1.25 mil) is modeled between the LTMS and the MUT to account for the air gap problem discussed above.

FIG. 5H and FIG. 5I show the cost function based on measurements of crosslinked polystyrene (Rexolite) and high-density polyethylene (HDPE) evaluated against this parametric sweep.

In contrast to the LTMS substrate extraction exercise, the results here do not converge to a “point” in the global solution space at a specific loss tangent value; rather, some amount of ambiguity exists in the solution, implying a range of possible loss tangents. This loss of sensitivity is primarily caused by the high loss tangent and real permittivity of the LTMS substrate, and for this, LTMS losses in the substrate dominate any small losses occurring in the MUT. Additionally, the problem is exacerbated by the much higher permittivity of the substrate, causing the electric field to be concentrated within the FR4 substrate. The effect of substrate permittivity is discussed in detail below.

Discussion on Loss Tangent Sensitivity. A necessary condition for the success of an LTMS is to be sufficiently capable of resolving small changes in loss tangent, particularly at very low levels of loss tangent (tan δ˜10⁻⁴). The LTMS described in previous sections is somewhat lacking in this regard, but not without cause; it was not designed for this purpose. However, it highlights the most important design condition for these surfaces: a low substrate loss tangent. The loss tangent of the LTMS substrates sets the lower bound for the loss tangent extraction. A substrate with a high-loss tangent provides limited sensitivity in resolving MUT loss tangents much below its own, as illustrated by the measurements of low-loss Rexolite and HDPE with the FR-4 LTMS.

Numerical analysis. A simple cross dipole FSS with periodicity Λ=0.2″ was modeled in FDTD to illustrate this behavior. The loss tangent of the substrate and MUT were each varied, and transmission null depth at the resonant frequency was recorded for each FDTD run. The LTMS measurement dependence is shown in FIG. 5J.

The ideal LTMS would have a null depth sensitive to changes in MUT loss tangent for all loss tangents, and a linear relationship across this range would provide interpolative potential. However, as the loss tangent decreases in the MUT, other sources of loss in the system become dominant contributors to the quality of the resonance. This loss of sensitivity manifests as “roll-off” in the linear relationship, where progressively smaller MUT loss tangents result in indistinguishable changes in the measured response. The dominant contributor to this roll-off is loss occurring in the LTMS substrate, for which the remedy is a substrate with a lower loss tangent.

### Example #2—Metasurface-Based Sensing

The scattering behavior of a metasurface is fundamentally a property of its design and its environment; it takes no large leap in reasoning to agree that a metasurface designed with a particular substrate in mind will not have the intended response if constructed on a substrate with different electromagnetic properties. If however this change in substrate (or conductor properties) is effected by some change in environment, and the mapping between environmental change and material property change is well-behaved and easily characterized, then a sensing mechanism arises. A variety of metasurfaces have been described which operate on the basis of changing refractive index of the materials adjacent to the metasurface, the most immediate application being to measure material properties directly. These refractive index sensors are often designed as high-Q structures for a narrow spectral response, as a narrower peak or null improves the precision of locating center of that null.

Discussion A necessary prerequisite for the design of all manners of electromagnetic structures is the characterization of the electromagnetic properties of the materials used in the design. The characterization of the permittivity of dielectric material is a characterization of a complex quantity, requiring measurement of two independent effects to obtain both dielectric constant and loss tangent. It is also of note that the real part of the permittivity may be many orders of magnitude larger than the imaginary part for low-loss materials, so different mechanisms to generate the measurable effect are required for each component, i.e., a complex measurement of transmission is not sufficient to accurately obtain a characterization of the complex permittivity.

Cavity perturbation techniques operate on a relatively simple premise; the measured characteristics of a resonator, typically the resonant frequency and the resonance bandwidth or Q-factor, are perturbed upon the introduction of some foreign object—the material under test—into the resonator [2′]. The degree of perturbation that occurs depends on the physical dimensions of the material under test, which are obtained prior to the characterization, and the permittivity of the material. Increasing real permittivity creates a corresponding downshift of the resonant frequency as the cavity becomes “electrically larger”, while the Q-factor, inversely proportional to the total losses in the cavity, decreases as material loss tangent increases.

Design of a loss tangent measurement surface. The use of metasurfaces for the characterization of complex permittivity has been extended to microwave frequencies, both in waveguides [3′-5′] and in free space [1′]. In contrast to the RIS at optical frequencies, at microwave frequencies is often desirable to obtain not only the real part of the permittivity but the loss factor as well since dielectric losses tend to overshadow metal losses at these lower frequencies. In addition, many of the design parameters available at optical frequencies may not be found at microwave frequencies; for example, both metal and substrate thicknesses are often fractions of the wavelength. The loss tangent measurement surface (LTMS) extends the conceptual framework of the RIS by leveraging cavity perturbational techniques to estimate the loss tangent (in addition to the dielectric constant) of dielectric materials under investigation.

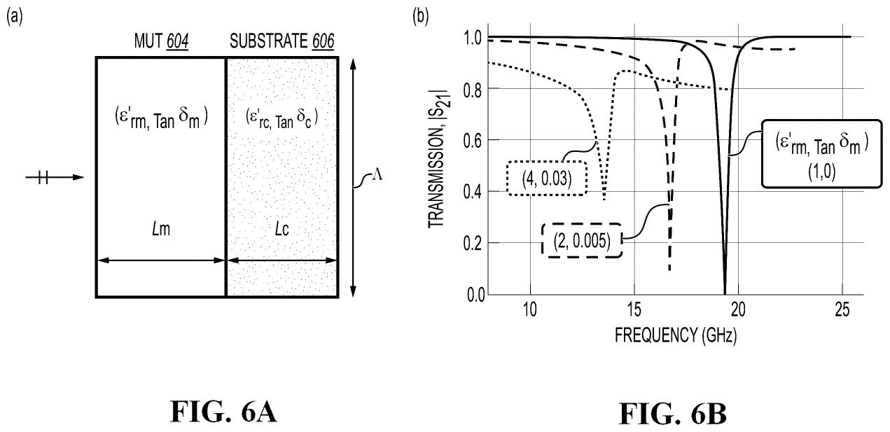

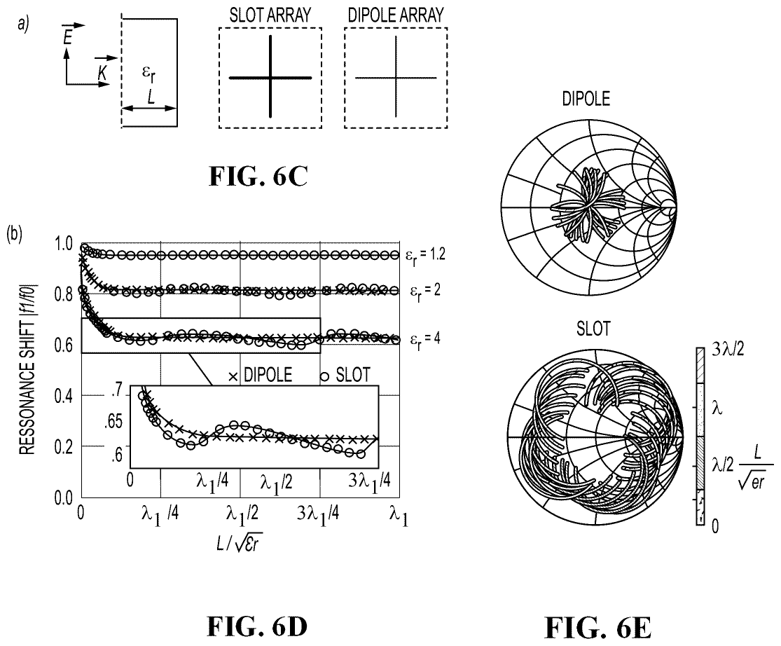

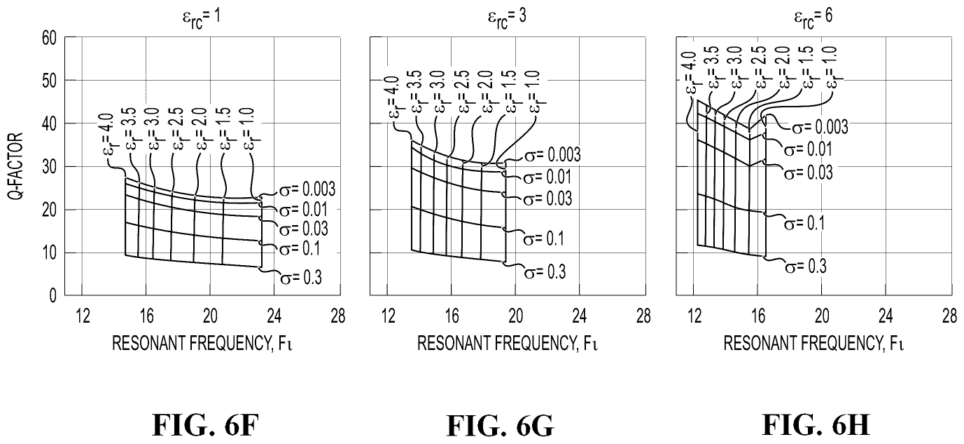

FIG. 6A shows the universal geometry for studying the LTMS consisting of a material under test (MUT) 604 placed against a substrate-backed metasurface 606 with unit cell periodicity Λ, illuminated by a plane wave. The metasurface, with unit cell periodicity Λ, was fabricated on a carrier substrate with real relative permittivity εᵣₘ′, loss tangent, δₘ, and thickness L_{C}. The dielectric material under test (MUT) similarly has dielectric parameters εᵣₘ′ and tan δₘ with thickness L_{M}. In this study, metasurfaces with 4-fold rotational symmetry were considered for polarization insensitivity. The perturbational techniques leveraged in cavity resonators for complex permittivity characterization are applicable to metasurface sensing.

FIG. 6B is a graph illustrating that varying the dielectric constants εᵣₘ′ and loss tangent tan δₘ of the MUT changes the resonant frequency and Q-factor of the system. Similar to the perturbational techniques leveraged in cavity resonators, variation in the dielectric constant and loss tangent of the MUT results in changes in the resonant frequency and Q-factor, respectively, as shown in FIG. 6B.

Given the large design space afforded by even this simple metasurface, various design decisions lead to an LTMS with improved sensitivity. Considerations include the selection of slot- vs. obstacle-based patterns, periodicity of the unit cell, and supporting substrate material and thickness.

This work leverages a perturbational behavior observed in metasurfaces for dielectric sensing that is similar to perturbations observed in cavity resonators. Metasurfaces present an impedance discontinuity at a particular plane, with varying reactance brought about through the careful tailoring of a periodic metal/dielectric pattern. The choice of pattern creates frequency-dependent behavior reminiscent of canonical RLC circuit topologies [6′, 7′]; induced currents on conductive traces aligned with the electric field produce circulating magnetic fields around the conductive element, producing an inductive reactance. The ends of these conductors accumulate charge from the induced current, and fringing fields between the conductors are capacitive in nature. It is this localization of fields that provide a mechanism for sensing; just as the resonant cavity spatially confines fields within its conducting walls, the metasurface has rapidly decaying evanescent fields that are effectively confined to the region near the metasurface.

Permittivity dependence and choice of slots or dipoles. Permittivity dependence and choice of slots or dipoles. For a freestanding metasurface with resonant frequency f₀, addition of a dielectric on one side of the surface will cause the resonant frequency to shift, approaching f₀/\sqrt{(εᵣ+1)/2} as the thickness of the dielectric approaches an infinite half-space. Dielectrics of a finite thickness will have a resonant frequency generally above this lower limit; however, convergence happens rather quickly, in some examples, covering 90% of the distance.

For dielectric characterization purposes, it is desired that the resonant frequency remain constant with thickness for two reasons. First, variation in the resonant frequency versus thickness adds additional complexity to the relationship between resonant frequency and permittivity, which can turn an easily solvable analytic relationship into one requiring iterative or even computational electromagnetics solutions. Second, once a relationship between thickness and resonant frequency is established, any thickness measurement errors will be propagated into the calculated permittivity value, reducing measurement accuracy. The choice of aperture (“band pass” filters such as slots) versus obstacle (“band-stop” filters such as dipoles) unit cells for the resonant structure is strictly determined by this consideration. Because the dipole metasurface has zero reactance at resonance, any shunt admittances introduced by neighboring dielectrics have no effect on the resonant frequency. The slot, on the other hand, is a high impedance, reactive surface at resonance. The neighboring dielectric, as a short section of the transmission line, presents a reactance in parallel with this impedance, which varies cyclically with thickness, causing a variation of the resonant frequency around the anticipated limit, as illustrated in FIG. 6A, FIG. 6B, and FIG. 6C-E. The dipole band-stop surface is, therefore, preferred over the slot for dielectric characterization metasurfaces. A useful abstraction of this effect is the effective permittivity ε_{r,eff}, which is the permittivity of an infinite half-space that would generate the same resonance shift as the dielectric of finite thickness. As demonstrated in the comparison of slots and dipoles, this effective permittivity is dependent on the geometry of the metasurface; not only do the two topologies have vastly different behavior in the limit for large thicknesses, but the choice of geometrical dimensions within a particular topology affects the rate of convergence of ε_{r,eff}→εᵣ as t→∞. This rate of convergence for a set of dipoles with the same length (and consequently the same resonant frequency) but varying periodicity of the unit cell is shown in FIG. 6F, FIG. 6G, and FIG. 6H. For the two-sided geometry shown in FIG. 6A, the expected resonance shift is provided in Equation 2.

$${f}_{1} = {f}_{0} / \sqrt{\frac{{ε}_{rm , eff}^{′} + {ε}_{c m , eff}^{′}}{2}} \qquad ( Eq . 2 )$$

In Equation 2, ε_{rm,eff}′ and ε_{cm,eff}′ are the effective permittivities of the MUT and the substrate, respectively.

### Example #3—Characterization of Dielectrics Using Metasurface-Based Cavities

Embodiments of the present disclosure developed multiple enabling tools for the design of material characterization metasurfaces: computationally efficient FDTD simulations with new modal analysis, equivalent circuit modeling techniques, Q-fitting algorithms, and plotting tools. These developments enabled analysis of canonical metasurface designs, exploring how choices in the geometry of the metallic pattern affect the sharpness of the metasurface resonance, which is captured in the figure of merit Q. Equivalent circuit modeling of these designs provide a theoretical underpinning and physical intuition into these effects, and revealed that large periodicity of a metasurface improves the Q-factor. A suite of five metasurfaces was designed to cover the frequency band from 8-12 GHz, and measurements in the focused beam showed good agreement with the model in both resonant frequency and Q.

The performance of any metasurface for material characterization is governed by the strength of its resonance. A resonant structure is one that stores energy and decay of that stored energy occurs through the energy that “escapes” through radiation or that is converted into heat through dielectric or conductor losses. In order to maximize the sensitivity of the metasurface to small changes in dielectric loss—the dielectric being the material with unknown permittivity to be characterized—the conductor, dielectric, and coupling losses of the metasurface must be minimized. The strength of the resonance and, by extension, the magnitude of these losses is captured in a figure-of-merit called Q-factor, or simply Q. The formal definition of Q is provided in [9′] as:

$$Q = ω \frac{energy stored}{power loss} .$$

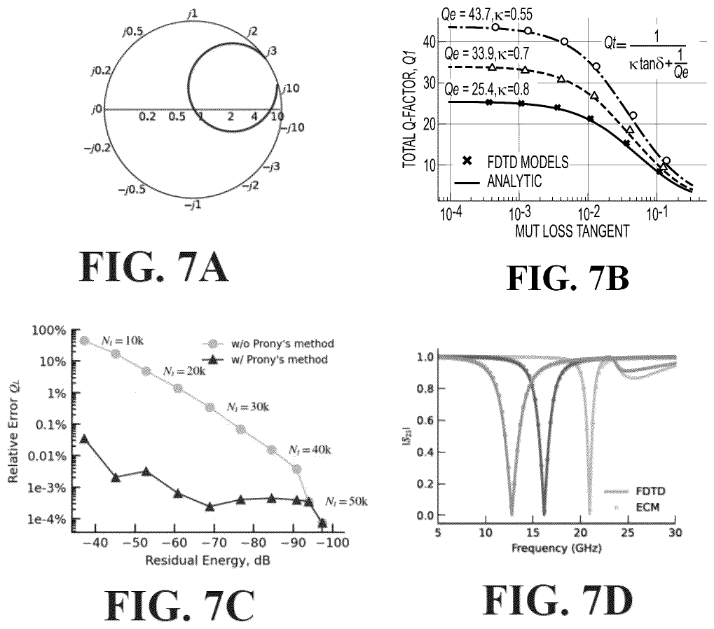

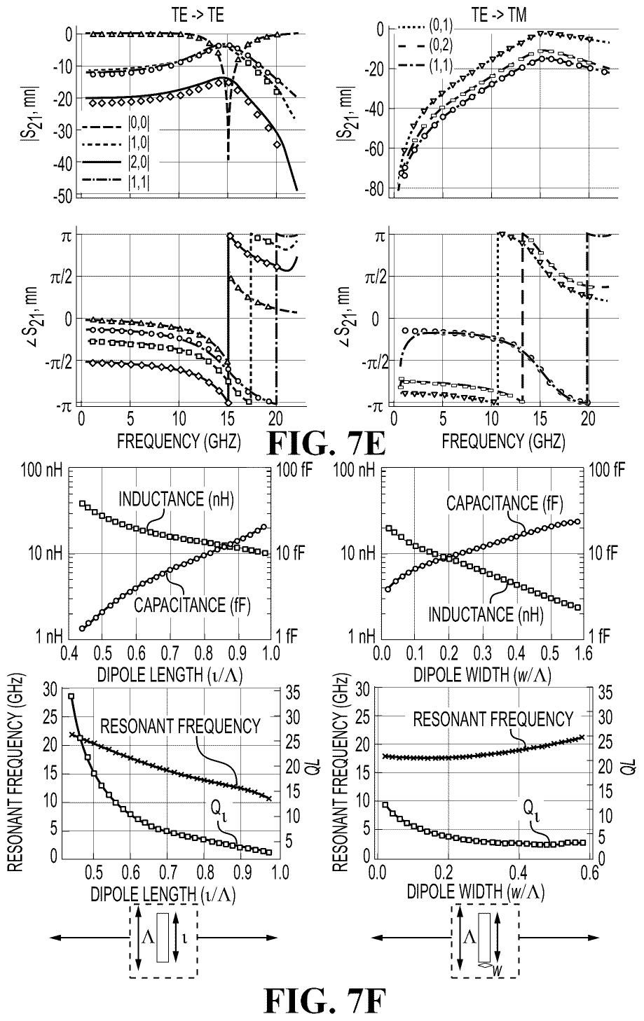

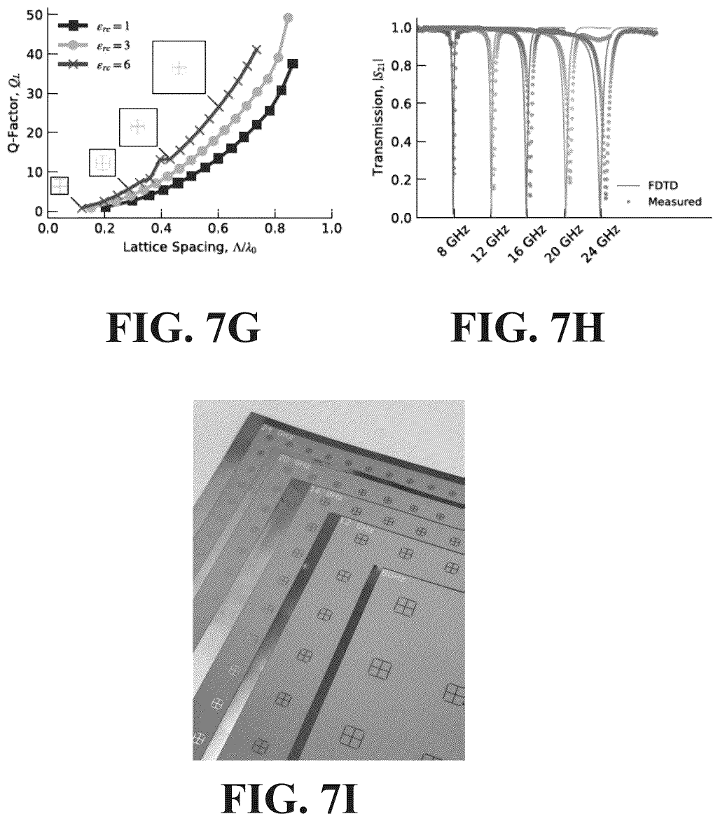

Analysis of the frequency response of lumped circuit resonators shows that this robust formulation is synonymous with the much more familiar “three-point” definition

$$Q = \frac{{f}_{0}}{Δ f}$$

where f₀ is the resonant frequency and Δf the half-power bandwidth. The convenience of such a definition is undeniable; the estimation of Q from a chart of resonator frequency response or even directly from a network analyzer screen is trivial. While the three-point method is graphically useful, computer processing of measurement data enables more advanced Q computation that is resilient to noise, interpolation errors, and transmission-line-induced skew. This technique leverages the fact that the scattering parameters from a resonance appear as a circle in the complex plane, as shown in FIG. 7A, which depicts a resonance in the complex s-plane charted alongside impedances on a Smith chart. Q is extracted from an iterative fit of a linear fractional transform to the complex s-parameters, and is related to the rate at which the measurement proceeds around the Q-circle. The rate of change is fundamentally linked to the half-power bandwidth used in the three-point method, but instead of only sampling three data points, many tens or hundreds of data points are sampled to reduce measurement error.

Robust determination of the Q-factor was achieved through the implementation of the NLQFIT algorithm described in [10′]. Both the 6-term and 8-term models were implemented in Python and tested against analytic resonant frequency responses without and with overlaid noise.

The Smith chart is the visualization tool of choice for Q-circles and impedance data integral to the design of a metasurface, allowing impedance data and scattering parameters to be co-located on the same plot. This research effort supported the development of Smith chart plotting capabilities integrated into the widely-used Python library matplotlib. In contrast to other Python utilities for Smith charts, the approach used for this pluggable module defines the conformal map performed by the Smith chart as an affine transform directly in matplotlib, preserving all of matplotlib's native functionality, including scaling, grid lines, tick marks, labels, etc. and maintaining the same workflow for both Smith chart plots and Cartesian plots.

The Q figure of merit allows for a direct comparison of potential metasurface designs, and analysis of canonical patterns may proceed. The primary objective in the design of a material characterization metasurface is a high-Q resonance; this establishes the sensitivity of the measurement to dielectric loss in the load since measured Q follows the relationship per Equation 3.

$${Q}_{total} = \frac{1}{k tan δ + \frac{1}{{Q}_{e}}} \qquad ( Eq . 3 )$$

In Equation 3, Qₑ is the initial Q of the metasurface against a lossless dielectric, k is a “filling factor,” and tan δ is the loss tangent of the material under test. This relationship is depicted in FIG. 7B, where it is seen that increasing the starting Q-factor Qₑ increases sensitivity at lower levels of loss tangent.

Transmission and reflection data for a particular metasurface design is obtained through full-wave electromagnetic simulations with MaxTDA, the Advanced Concepts Laboratory's finite-difference time-domain (FDTD) solver. To obtain accurate results, an FDTD simulation is typically run until the energy in the grid has decayed below some near-zero threshold.

However, when modeling highly resonant structures, slow decay of energy requires a very large number of time steps. To increase the computational efficiency of these simulations, Prony's method [11′] was implemented to extrapolate the decaying fields in a truncated FDTD simulation to convergence. FIG. 7C shows the added efficiency of Prony's method on the extraction of loaded Q-factor, Q′. Without in any way denigrating the usefulness of computer simulations combined with parametric sweeps or optimizations to determine an optimal engineered design, it is worth noting that these two tools alone provide an engineer no intuition into the link between physical metasurface geometries and their resulting scattering parameters. Such intuition may be discovered, at least for the simple canonical designs discussed here, by representing the physical features of the metasurface as lumped circuit elements—regions of current flow as inductors, gaps between metallic elements as capacitors, and radiation to free space as a real impedance [12′]. If a circuit topology and component values can be determined so as to sufficiently match the frequency response of the actual metasurface, then Q can be solved directly. For example, the Q of a series RLC circuit (a transmission notch or bandstop filter) can be defined as:

$$Q = \frac{1}{R} \sqrt{\frac{L}{C}} .$$

From such an equivalent circuit model (ECM), one can intuit physical means of increasing the Q of the metasurface, for example, by reducing capacitance in the circuit by increasing the inter-element spacing between dipole elements. Insights into design requirements for material characterization metasurfaces are discussed herein.

For many metasurface topologies, a single resonant RLC circuit is capable of capturing the important behavior of the frequency response near the resonant frequency, as in FIG. 7E. FIG. 7E are a series of graphs illustrating a mode extraction technique that was developed to capture the scattering parameters for higher-order evanescent modes from an FDTD simulation (lines), and validated against a mode-matching algorithm (dots). However, a more robust circuit equivalent model of the interaction of metasurface with surrounding materials, such as dielectric slabs or other metasurfaces, requires the inclusion of the effects of higher-order evanescent modes, where energy from the propagating mode is coupled into the evanescent mode and interaction with the metasurface represented as a different circuit for each mode [13′]. To obtain the amount of coupling associated with each mode, the fields sampled on a plane parallel to the metasurface in a periodic FDTD simulation may be decomposed into an angular spectrum of plane waves, where the spectrum is discretized into propagating and evanescent “angles” or “modes” [14′]. The mode extraction technique was developed and validated against ACL's mode-matching code TENZ, as shown in FIG. 7E.

Technical Results. FDTD simulations were used in conjunction with equivalent circuit modeling to create design guidelines for high-Q metasurfaces. A simple dipole metasurface was used as a starting point for this analysis. It is well understood that the length of a dipole is the primary determining factor of a nonperiodic dipole's resonant frequency, while fattening the dipole's width causes an increase in bandwidth and, consequently, a decrease in the dipole's Q-factor.

FIG. 7F shows this relationship for a periodic planar dipole, extracting equivalent circuit parameters to demonstrate their effect on resonant frequency and Q-factor. While a wider dipole does show decreasing Q due primarily to the decreasing inductance of the dipole, it is somewhat surprising that this effect is much smaller than the change in Q due to dipole length relative to periodicity in determining the Q of the metasurface. This is primarily because in a periodic dipole array, coupling between the ends of the dipole rapidly increases the mutual capacitance between the elements, lowering the Q of the resonant structure. To test the hypothesis that decreasing coupling between adjacent elements is a key requirement in the design of a material characterization metasurface, the size of a resonant element is fixed so as to maintain the same resonant frequency, and the interelement spacing of the periodic array varied, as shown in FIG. 7G.

As the inter-element capacitance goes down due to increased space between the elements, the Q-factor goes up rapidly. In fact, the limit as the lattice spacing approaches Λ/λ!=1 is Q→∞. However, this high Q is because of trapped surface waves due to grating lobe onset, which is highly unstable and should be avoided. An optimal design value of Λ/λ!=0.75 was chosen to maximize Q and maintain some distance from the frequency at which grating lobes occur.

With this design requirement in mind, a suite of dielectric characterization surfaces based on the canonical Jerusalem Cross shape were designed and fabricated. The five surfaces are designed on 0.010″ Rogers 3003 substrate (ϵᵣ=3.0, tan δ=0.002), with resonant frequencies of 8, 12, 16, 20, and 24 GHz, enabling multi-octave material characterization. The samples were designed against FDTD simulations and measured in the focused beam system; FIG. 7H shows good model-measure agreement, although a small deviation in the resonance frequencies occurs at the higher frequencies, likely due to slight over-etching of the cross elements. FIG. 7I depicts a suite of metasurfaces of the Jerusalem Cross shape designed on 0.010″ Rogers RO-3003 substrate (ϵᵣ=3.0, tan δ=0.002).

The loss tangent measurement surface can thus be used for sensitive loss tangent characterization for low-loss materials in a free-space-focused beam system. To validate, transmission through an existing one-sided FSS was measured in isolation and applied to various low-loss dielectric materials. An FDTD model assisted extraction of complex permittivity through parametric techniques.

### A Dual-Resonance Frequency Selective Surface Genetically Optimized for Dielectric Characterization

Embodiments of the present disclosure optimize an FSS using an evolutionary algorithm to generate a dual-resonance response to double the number of spot frequencies available for complex permittivity characterization.

Design of the FSS. The design of the FSS requires a parametrized finite-difference time-domain (FDTD) model of the periodic surface. The scattering parameters of the FSS are then tailored using a multi-objective genetic algorithm (MOGA) with a cost function that promotes the dual resonance character.

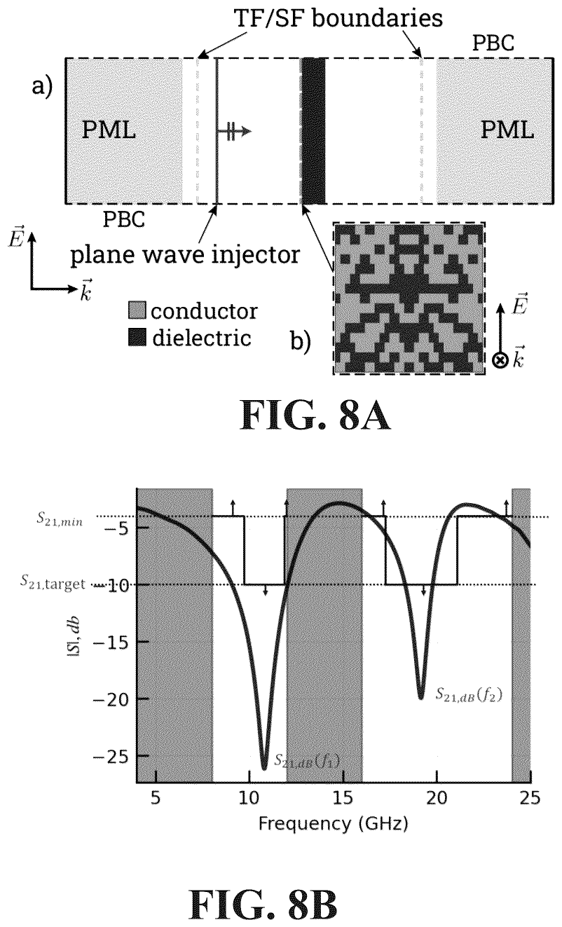

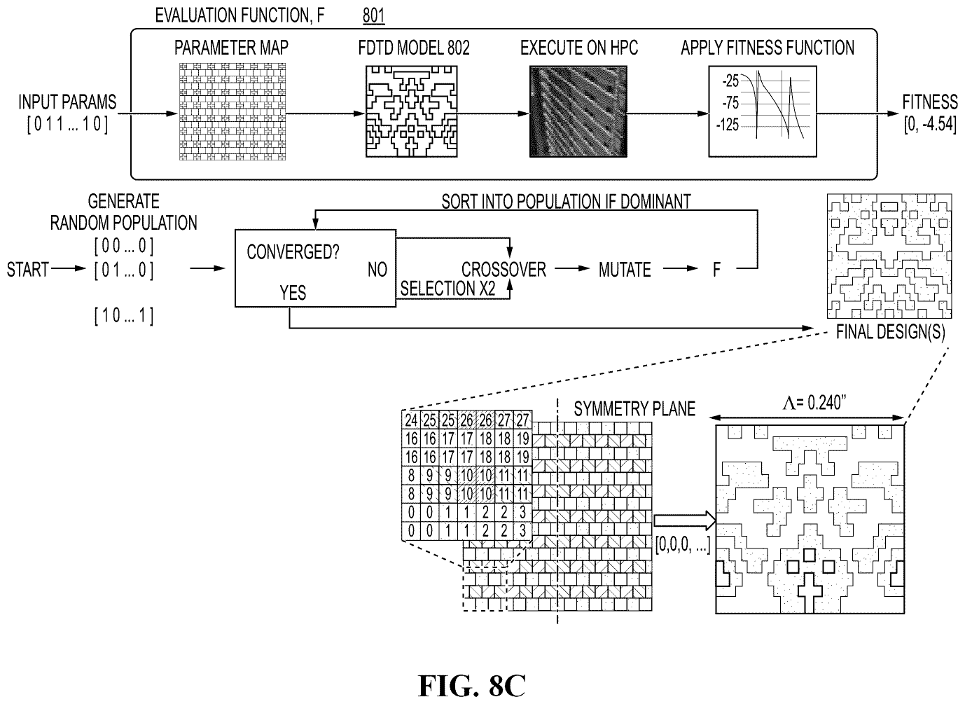

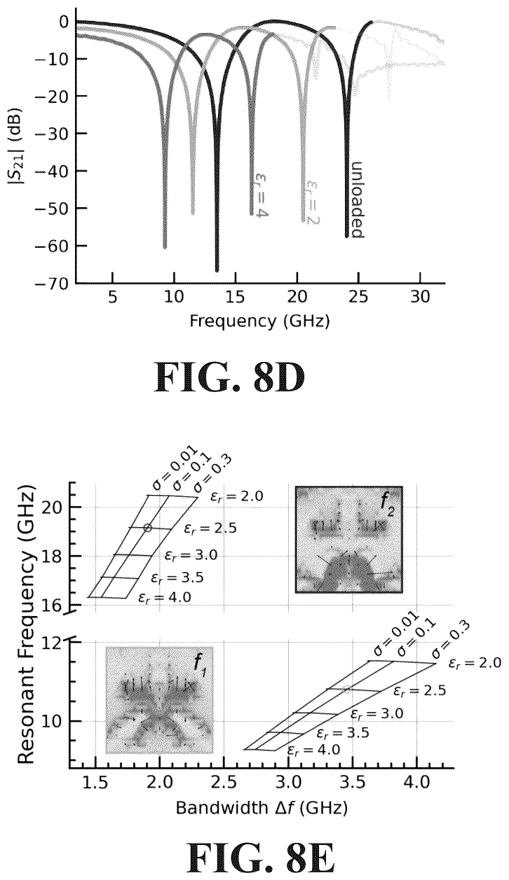

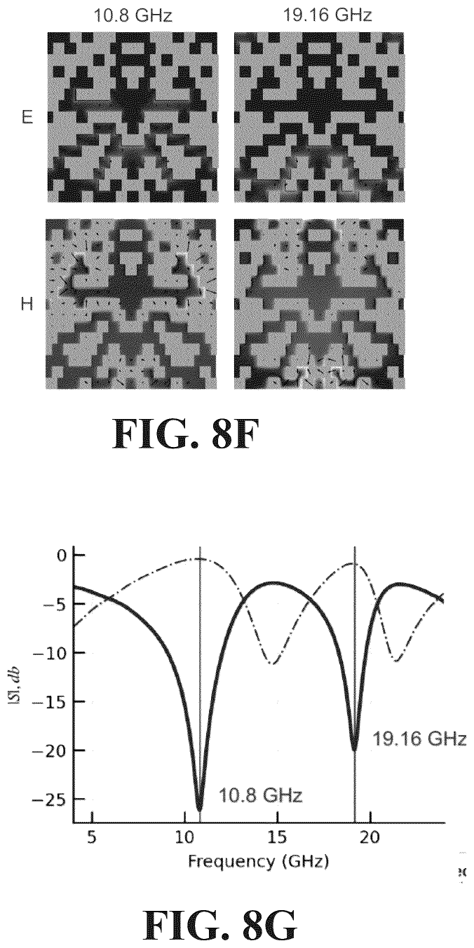

FDTD Model. FIG. 8A depicts an FDTD model of the FSS geometry showing a) the plane of propagation, including the location of the injector and transform surfaces, and b) the periodic surface itself with the propagation vector into the page. The scattering parameters for the FSS are simulated by an FDTD code. A single unit cell of the FSS (0:240″×0:240″, Δx=Δy=Δz=0:002″) is modeled with periodic boundary conditions (PBCs) as shown. The FSS is of the fragmented type [18′], with the thin metallic sheet supported by a 0.010″ thick substrate of Rogers RT/Duroid 5880 material [19′], which was chosen for its low loss tangent (ϵᵣr=2:20, tan=0:0009). FIG. 8B is a graph illustrating an objective function with multiple objectives for a first band, f₁ (8-12 GHz) and a second band, f₂ (16-24 GHz). The first term ensures transmission null in the band and the second term maximized out of band transmission.

Optimization with a Multi-Objective Genetic Algorithm (MOGA). An in-house, Python-based MOGA was used to optimize the pixelated pattern of the fragmented element—metal is encoded as a “1” in the parameter vector and air as “0”. A flowchart of this MOGA is shown in FIG. 8C. As depicted in FIG. 8C, the genetic algorithm 801 creates offspring from a current population and evaluates them, mapping a binary vector to pixels on an FDTD model 802 and evaluating the model's performance against a cost function. Each resonance (N=0; 1) is treated as an independent optimization objective, with a cost function defined by the target resonant frequency f_{N} provided in Equation #4.

$${F}_{N} = min \{ 0 , {S}_{21 , d B} ( {f}_{N} ) - {S}_{21 , target} \} + \frac{1}{n} {( {\sum }_{i = 1}^{n} {( min \{ 0 , {S}_{21 , min} - {S}_{21 , d B} ( {f}_{iN} ) \} )}^{P} )}^{1 / P} \qquad ( Eq . 4 )$$

In Equation 4, S_{21,target}=−10 is the maximum allowed transmission in dB at the resonance, S_{21,min}=−4 is the minimum transmission out-of-band, and the summation is a weighted mean (p=8) over n out-of-band frequency points. For this optimization, the target resonant frequency was allowed to vary between 10 to 14 GHz for the lower band and 20 to 24 GHz for the upper band. The optimizer evaluated 1000 individuals out of the possible 2120 and achieved a suitable candidate on the 479th individual evaluated.

Dielectric Characterization. The location and quality factor of an FSS resonance changes when a sheet of dielectric material is placed immediately adjacent to the array of metallic elements. A dielectric material of thickness 0.120″ is added to the FSS model as a material-under-test (MUT), and a parametric sweep of complex permittivity values is performed.

The transmission curves for the unloaded FSS as optimized and for the loaded FSS (ϵᵣ=2; 4) are shown in FIG. 8D. FIG. 8D shows that the optimized FSS has two resonances at 13.5 and 24 GHz. The location and quality of the resonances change when the surface is affixed to a substrate of a given permittivity. A mapping of center frequency and bandwidth of resonance to complex permittivity is illustrated in FIG. 8E, showing the sensitivity of the FSS response to the MUT properties. Specifically, FIG. 8E shows a parametric sweep of dielectric material complex permittivities yields a mapping of measured resonant frequency. f_{N} and bandwidth, where loss tangent is tan

$$δ = \frac{σ}{{ωϵ}_{r}^{′} {ϵ}_{0}} .$$

Bandwidth is computed by fitting a circle to the transmission curve in the complex plane [35′]. This work shows that a dual resonance FSS may be optimized to achieve sensitivity (˜tan δ=0.002) to complex permittivity for dielectric characterization purposes. FIG. 8F depicts field maps corresponding with an optimized design for a dual-band resonant FSS for material characterization. FIG. 8F demonstrates the localization of distinct resonant regions in the optimized surface pattern at 10.8 GHz and 19.16 GHz, respectively. FIG. 8G is a corresponding graph showing that the second resonance (19.16 GHz) is not a harmonic of the first resonance (10.8 GHz).

### Example #4—Tunable Frequency-Selective Surface for Microwave Material Measurement Applications

Embodiments of the present disclosure present a hybridized technique for optimizing the tunable range of the surface; a finite-difference time-domain (FDTD) simulation is used to generate equivalent circuit parameters for a given surface pattern which are used as inputs to a circuit model, which incorporates a model for the tuning varactor diode. From this circuit model, an estimate for the tuning range is obtained. A multi-objective genetic algorithm is used to explore the trade-off between tunable range and FSS Q-factor, and an optimized design is evaluated for sensitivity to dielectric constant across the entire tuning range.

Design Process. The primary requirement for a material characterization FSS is a high Q-factor, as the measured Q of the resonance when the FSS is perturbed, Qp, adheres to cavity perturbation theory [24′] per Equation 5.

$${Q}_{P} = \frac{1}{k tan δ + \frac{1}{{Q}_{L}}} \qquad ( Eq . 5 )$$

In Equation 5, tan δ is the loss tangent of the material to be measured, k is a geometry-dependent filling factor, and QL is the Q-factor of the FSS against a lossless substrate. The sensitivity of the measurement to low levels of loss is largely determined by the starting Q of the FSS, which should be as high as possible.

An Equivalent Circuit Model for Band-Stop Frequency-Selective Surfaces. When an incident electromagnetic wave strikes a frequency-selective surface, it induces currents along the metallic elements of the surface, the reradiation of which creates a tailored response in reflection and transmission [8]. When the wavelength is substantially larger than the periodicity of the FSS, far away from the onset of any diffractive orders, this behavior may be homogenized such that the electromagnetic response at each frequency is represented by some effective shunt impedance Z_{fss}[18′]. The impedance looking into the FSS is therefore: Zᵢₙ=Z_{fss}∥Z₀.

Of course, the frequency-selective nature of an FSS must imply some frequency-dependent variation of Z_{fss} which is determined by the patterning of metal on the surface. Equivalent circuit modeling (ECM) is a powerful technique for capturing this frequency dependence, which recognizes that the electric and magnetic fields around the surface obey the same physical principles as ideal circuit components: time-varying current flow results in magnetic fields as in an inductor and electric fields between adjacent metallic elements are inherently capacitive.

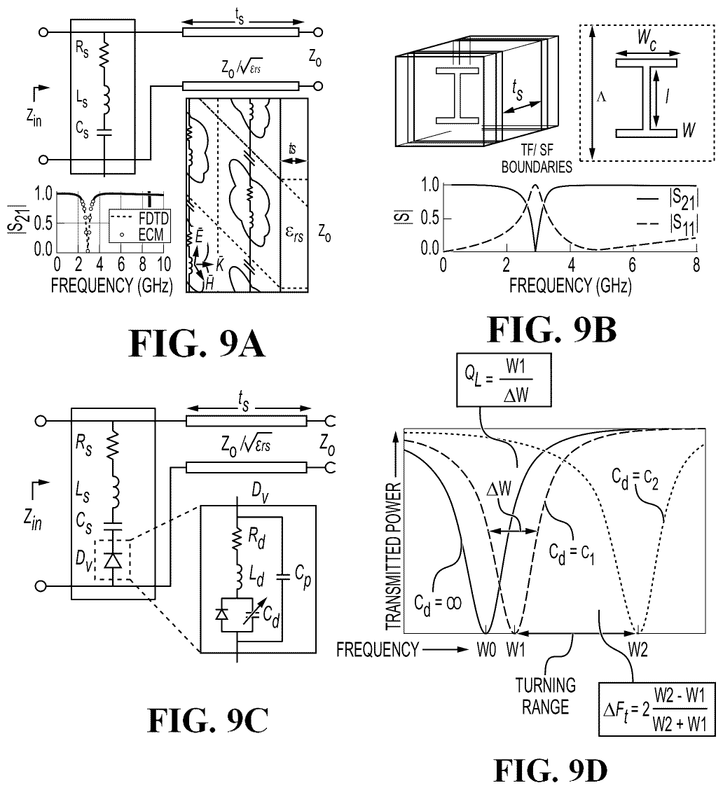

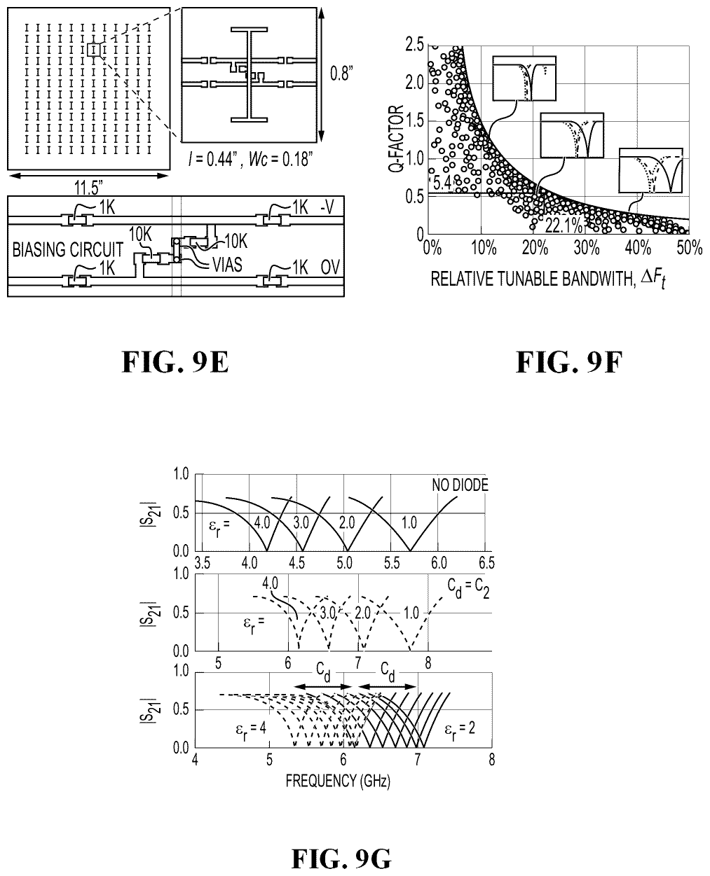

The simplest representation of a band-stop FSS is the series RLC circuit depicted in FIG. 9A, which, in the absence of an underlying substrate, has the input impedance looking into the FSS: Zᵢₙ=(Rₛ+jXₛ)∥Z₀, where Xs (ω)=ωLs−1/(ωCs). The reflection coefficient for this input impedance can be provided as

$$Γ = \frac{- {Z}_{0}}{{Z}_{0} + 2 {R}_{s + {jX}_{s}}}$$

where a maximum value is provided when the reactance is zero at the resonant frequency ω₀=/\sqrt{LₛCₛ}. The Q-factor of this band-stop FSS may be obtained from the fractional bandwidth definition [25′] of Q where

$$Q = \frac{{ω}_{0}}{{ω}_{+} - {ω}_{-}}$$

in which ω₀ is the resonant frequency and ω₋ and ω₊ denote the half-power points of the reflection coefficient on either side of the resonance. By this definition, the resulting Q-factor of the equivalent circuit is

$${Q}_{L} = \frac{2}{{Z}_{0} + 2 {R}_{s}} \sqrt{\frac{{L}_{s}}{{C}_{s}}} .$$

The presence of the supporting substrate for the metasurface is incorporated into the ECM as a transmission line of length. tₛ with characteristic impedance Z₀/\sqrt{ϵᵣₛ}. However, a more flexible approach is to directly calculate the symmetric scattering parameters for normal incidence on a dielectric slab, per Equation 6.

$${S}_{11} = {S}_{22} = \frac{Γ ( 1 - {T}^{2} )}{1 - {Γ}^{2} {T}^{2}} {S}_{12} = {S}_{21} = \frac{T ( 1 - {Γ}^{2} )}{1 - {Γ}^{2} {T}^{2}} \qquad ( Eq . 6 )$$

In Equation 6, Γ=(1−\sqrt{ϵᵣₛ})/(1+\sqrt{ϵᵣₛ}) and T=exp {−jωtₛ\sqrt{ϵᵣₛ}/c} and cascade them with the symmetric S-parameters from the FSS impedance.

An analytic relationship between the shape of an FSS element and its equivalent circuit parameters exists only for a few simple elements. The utility of the ECM technique has been more often found in retrieving circuit parameters from a full wave simulation then using that circuit topology to provide physical intuition of the circuit. For this work, circuit parameters are retrieved from FDTD simulations. For a given resonant frequency ω₀ computed from simulated transmission data, curve fitting (Nelder-Mead least squares) is used to calculate Cs and Lₛ1/ω²Cₛ by fitting transmission data calculated from the ECM to the FDTD data.

FDTD Modeling of End-Loaded Dipole. The end-loaded dipole or “dogbone” FSS shape [26′], shown in FIG. 9B, has single-resonance band-stop response very similar to a simple dipole FSS, with an added degree of freedom to vary the ratio of inductance to capacitance at a desired resonant frequency through adjustment of the size of end loading.

The importance of this degree of freedom is apparent in [24′]; maximizing inductance relative to capacitance is necessary to improve the Q-factor of the resonance, although minimizing capacitance also has implications for the tuning range of the tunable FSS.

To enable optimization of the unit cell, the FDTD model is parameterized. In particular, the length of the dipole l, the width of the end-loading w_{c}, and the periodicity of the unit cell Λ are allowed to vary, while the width of the metal traces w=0.51 mm (0.020 in), thickness of the substrate ts=1.52 mm (0.060 in), and substrate permittivity ϵᵣₛ=3.0 are fixed. The unit cell geometry is discretized onto an FDTD grid with cell size Δ=0.25 mm (0.010 in). Each simulation is run for 3.83 ns (8,000 time steps), and Prony's method as described in [11′] is used to extrapolate accurate frequency domain data from remaining residual energy contained in resonances. An example simulated frequency response is shown in FIG. 9B.

Tuning FSS resonant frequency. The central element of the dogbone FSS—the dipole—is a current-carrying conductor with inductance. Inserting a gap into the conductor in effect, replaces the small inductance associated with that section of conductor with a capacitance in series with the existing RLC circuit, which has the overall effect of raising the resonant frequency slightly since ω₀=1/\sqrt{LₛCₛ}. A lumped capacitor placed across this gap is effectively a series capacitance, lowering the overall series capacitance and raising the resonant frequency further. If a lumped inductor is placed across this gap, the overall series inductance increases, lowering the resonant frequency.

To maximize the Q-factor of a tunable FSS, ideally, the surface pattern would be designed to maximize the series inductance Ls relative to Cs, with an additional series variable inductor used to create a tunable resonant frequency. The benefit of such a scheme over the use of some form of lumped variable capacitance is twofold. First, variation in the reactance of the circuit comes from manageable levels of inductance—tens to hundreds of nH—instead of the fF levels of capacitance—much smaller than the unwanted parasitics associated with many physical components—required to tune the FSS. Second, the sensing mechanism for dielectric characterization involves the relative permittivity of the material under test, altering the unit cell capacitance Cs; charge stored in the lumped capacitor instead of the surrounding dielectric weakens the sensitivity of the measurement to real permittivity.

Unfortunately, variable inductors at microwave frequencies are elusive [27′], with MEMS switching between banks of inductors as one of the more mature approaches [28′]. These switched inductors suffer from a low Q-factor, primarily from a high series resistance, are bulky, and few commercial-off-the-shelf solutions exist. On the other hand, varactor diodes have an established history of providing bias voltage-dependent capacitance for RF tuning applications [8′].

Small-Signal Varactor Representation. The equivalent circuit model is especially useful for the design of active metasurfaces, as it describes how the integration of both passive and active components will affect the electromagnetic response of the structure. A tunable FSS is necessarily a multiple-state system, and running separate full-wave simulations for each state is computationally expensive. Instead, a single full-wave simulation may be used to retrieve equivalent circuit parameters for the simple RLC circuit, then the circuit topology may then be expanded to include additional components. For simple circuit modifications such as the addition of lumped passive components, the updated FSS surface impedance may be solved analytically, as in this work. For more complex circuit modifications involving nonlinear components and amplifiers, or if higher-fidelity modeling including parasitics and high-frequency non-idealities is desired, it may be necessary to use a circuit solver such as SPICE or ADS to calculate the system's frequency response [30′].

While in general, a diode has a complex nonlinear voltage-current relationship, for this low-power application, a small signal approximation consisting only of resistors, inductors, and capacitors is sufficient [31′], as shown in FIG. 9C. The small signal model consists primarily of a variable junction capacitance Cd, with series resistance Rd and parasitic inductance Ld, as well as a parallel package capacitance Cp, which may potentially be neglected at high frequencies.

For a given FSS design with resonant frequency wo, adding a biased varactor diode in series with an FSS element yields a new resonant frequency per Equation 7.

$${ω}_{d} = \frac{1}{\sqrt{( {L}_{s} + {L}_{d} ) ( {C}_{s} ‖ {C}_{d} )}} \qquad ( Eq . 7 )$$

The tunable behavior of the FSS is shown in FIG. 9D. If the parasitic diode inductance is substantially smaller than the unit cell inductance, i.e., Ld<<Ls, then the resonant frequency may be approximated per Equation 8.

$${ω}_{d} \approx {ω}_{0} \sqrt{\frac{{C}_{s}}{{C}_{d}} + 1} \qquad ( Eq . 8 )$$

For Cd>>Cs, ωd˜ω0 and no tunability occurs, so it is important that the varactor diode provide a junction capacitance of the same order of magnitude or lower than the unit cell capacitance of the FSS. For a given diode with the junction capacitance range Cd: [C2,C1], the resulting tuning range is ωd:[ω1,ω2].

As a comparative figure of merit for the tuning range, the relative tunable bandwidth is defined as the tunable range divided by the mean tunable frequency,

$$Δ {f}_{t} = 2 \frac{{ω}_{2} - {ω}_{1}}{{ω}_{2} + {ω}_{1}} .$$

Design and Optimization of Tunable FSS. A GaAs hyperabruct varactor diode (MacomMAVR-011020-1411 [8]) was selected to provide a varying capacitance. For a varying reverse bias of 0 V to 15 V, this diode presents a series junction capacitance, C_{d}, of 0.036 pF to 0.23 pF with a series resistance of 13.2Ω.

Because the material characterization FSS relies on intimate contact between the metal pattern of the FSS and the material being tested, no electronic circuitry may be placed on the same side of the substrate as the surface. Instead, vias are used to route current at the broken center of the dipole to the backside of the substrate, where the varactor diode and any biasing circuitry is placed, as shown in FIG. 9E.

Biasing circuitry poses a challenge for the design of reconfigurable metasurfaces, as any biasing traces parallel to the incident electric field will couple energy, creating spurious resonances and potentially detuning the fundamental resonance. The bias lines are run orthogonal to the dipole to minimize the coupling of RF energy into the lines. Because the expected reverse saturation current of the chosen diode is so low (<100 nA), resistive bias lines were chosen for RF isolation, with lumped resistors—two 1 kΩ resistors per unit cell—along each bias line. In addition, one 10 kΩ resistor was placed as close as possible to the diodes to mitigate any capacitive loading from the bias traces. While the bias lines are designed so that the FSS with biasing circuitry generates as close of a response as possible to the FSS without, the added electrical length of thru vias slightly lowers the resonant frequency of the FSS, and other parasitics are unavoidable. However, many of these can be captured in the equivalent circuit model, so the biasing traces are added to the FDTD model, with a thin wire at the diode location and lumped resistors modeled directly in the FDTD update equations.

A multi-objective genetic algorithm—a Python implementation of non-dominated sorting genetic algorithm II (NSGAII) [33′]—is used to explore the trade-off space between tunable bandwidth and Q-factor at a low resonant frequency of f1=6 GHz [19]. The parameterized geometry is allowed to vary in periodicity Λ, dipole length l, and end-loading width wc, and an FDTD simulation of each geometry is run to obtain equivalent circuit parameters for the basic RLC circuit of FIG. 9A. The diode parameters are incorporated into a modified equivalent circuit in FIG. 9C to obtain expected transmission at for Cd=C1 and Cd=C2, from which ω1 and ω2 are obtained. The maximum Q-factor over the tunable range is obtained by fitting a Q-circle to the transmission response calculated at Cd=C1 using the NLQFIT algorithm [10′]. The individual is then scored against competing objectives of maximizing both Q and Δ ft, while the frequency ω1=ωtarget=2π(6 GHz) is ensured by subtracting from each fitness component a penalty function per Equation 9 scaled by a factor of 25 for the Q-factor metric and 0.6 for the Δ ft metric.

$${F}_{p e n a l t y} = ( \frac{{ω}_{1} - {ω}_{target}}{{ω}_{target}} ) \qquad ( Eq . 9 )$$

A total of 5000 individuals were evaluated by the genetic algorithm, which represents 18% of the total search space as defined. The Pareto frontier for the optimization is shown in FIG. 9F, illustrating a definite and well-behaved tradeoff between the competing objectives of Q-factor and tunable bandwidth. An intermediate Pareto-optimal solution is chosen as a study case for a design, which has a relative tunable bandwidth of 22.1% and a maximum Q-factor of 5.4.

Discussion on Material Measurement. It is well understood that the addition of dielectric materials on either side of an FSS causes a downward shift in the resonant frequency by as much as a factor of \sqrt{ϵᵣ′}, where ϵᵣ′ is the real relative permittivity of the material [8]. This downward shift is principally caused by changes in the wave number for evanescent fields from the surface-confined to the dielectric medium, which shows up in the ECM as a scaling of the capacitance by ϵᵣ, not unlike the scaling of capacitance that occurs when the material in a parallel plate capacitor is replaced with that of a higher dielectric constant.

The applicability of tunable FSSs to material characterization depends on whether or not the addition of external capacitance into this equation has a deadening effect on the required resonance shift. To test this effect, an FDTD-SPICE co-simulator was used to model the tunable FSS at different bias points.

The co-simulator samples magnetic fields around a SPICE port location in the FDTD grid, then injects these fields as current into a transient SPICE simulation, treating the FDTD grid as a Norton equivalent source. The voltage across the SPICE port calculated by the transient simulation is then used to update the electric field in the FDTD grid [34′].

The resonance shift due to a 6.1 mm (0.240 in) slab with varying real permittivity ϵᵣ′: [1.0, 4.0] is simulated with the FDTD-SPICE co-simulator for both the FSS with no diode and the FSS with diode capacitance Cd=C2. FIG. 9G shows the results of these simulations. While the amount of resonance shift decreases slightly with the incorporation of an external capacitance, it is not detrimental to the measurement. More work, however, is needed to quantify this effect.

Equivalent circuit modeling is an important technique that allows the design of circuitry for reconfiguration of an FSS to be decoupled from the design of the actual surface of the FSS. By obtaining an equivalent circuit for the surface itself, further analysis of the hardware “behind” the FSS can be performed analytically or using fast circuit solvers. This work demonstrated the use of the ECM technique to design a dielectric sensing FSS with 22% tunable bandwidth. Exploration of the design space via a genetic algorithm optimization revealed that hard limits exist for FSS tunability, which are a function of the properties of the diode, namely its capacitance range Cd, not of the shape of the FSS surface. Improvements in both tunable bandwidth and Q-factor can only come from better diodes—lower series resistance, wider capacitance ranges, and lower minimum junction capacitance. It is also worth exploring alternative approaches for generating extremely small levels of variable capacitance.

### Example Computing Device

Referring to FIG. 10, an example computing device 1000 upon which the methods described herein may be implemented is illustrated. It should be understood that the example computing device 1000 is only one example of a suitable computing environment upon which the methods described herein may be implemented. Optionally, the computing device 1000 can be a well-known computing system including, but not limited to, personal computers, servers, handheld or laptop devices, multiprocessor systems, microprocessor-based systems, network personal computers (PCs), minicomputers, mainframe computers, embedded systems, and/or distributed computing environments including a plurality of any of the above systems or devices. Distributed computing environments enable remote computing devices, which are connected to a communication network or other data transmission medium, to perform various tasks. In the distributed computing environment, the program modules, applications, and other data may be stored on local and/or remote computer storage media.

In its most basic configuration, computing device 1000 typically includes at least one processing unit 1006 and system memory 1004. Depending on the exact configuration and type of computing device, system memory 1004 may be volatile (such as random-access memory (RAM)), non-volatile (such as read-only memory (ROM), flash memory, etc.), or some combination of the two. This most basic configuration is illustrated in FIG. 10 by dashed line 1000. The processing unit 1006 may be a standard programmable processor that performs arithmetic and logic operations necessary for the operation of the computing device 1000. The computing device 1000 may also include a bus or other communication mechanism for communicating information among various components of the computing device 1000.

Computing device 1000 may have additional features/functionality. For example, computing device 1000 may include additional storage such as removable storage 1008 and non-removable storage 1010, including, but not limited to, magnetic or optical disks or tapes. Computing device 1000 may also contain network connection(s) 1016 that allow the device to communicate with other devices. Computing device 1000 may also have input device(s) 1014 such as a keyboard, mouse, touch screen, etc. Output device(s) 1012, such as a display, speakers, printer, etc., may also be included. The additional devices may be connected to the bus in order to facilitate the communication of data among the components of the computing device 1000. All these devices are well-known in the art and need not be discussed at length here.

The processing unit 1006 may be configured to execute program code encoded in tangible, computer-readable media. Tangible, computer-readable media refers to any media that is capable of providing data that causes the computing device 1000 (i.e., a machine) to operate in a particular fashion. Various computer-readable media may be utilized to provide instructions to the processing unit 1006 for execution. Example of tangible, computer-readable media may include, but is not limited to, volatile media, non-volatile media, removable media, and non-removable media implemented in any method or technology for storage of information such as computer-readable instructions, data structures, program modules or other data. System memory 1004, removable storage 1008, and non-removable storage 1010 are all examples of tangible, computer storage media. Examples of tangible, computer-readable recording media include, but are not limited to, an integrated circuit (e.g., field-programmable gate array or application-specific IC), a hard disk, an optical disk, a magneto-optical disk, a floppy disk, a magnetic tape, a holographic storage medium, a solid-state device, RAM, ROM, electrically erasable program read-only memory (EEPROM), flash memory or other memory technology, CD-ROM, digital versatile disks (DVD) or other optical storage, magnetic cassettes, magnetic tape, magnetic disk storage or other magnetic storage devices.

In an example implementation, the processing unit 1006 may execute program code stored in the system memory 1004. For example, the bus may carry data to the system memory 1004, from which the processing unit 1006 receives and executes instructions. The data received by the system memory 1004 may optionally be stored on the removable storage 1008 or the non-removable storage 1010 before or after execution by the processing unit 1006.

It should be understood that the various techniques described herein may be implemented in connection with hardware or software or, where appropriate, with a combination thereof. Thus, the methods and apparatuses of the presently disclosed subject matter, or certain aspects or portions thereof, may take the form of program code (i.e., instructions) embodied in tangible media, such as floppy diskettes, CD-ROMs, hard drives, or any other machine-readable storage medium where, when the program code is loaded into and executed by a machine, such as a computing device, the machine becomes an apparatus for practicing the presently disclosed subject matter. In the case of program code execution on programmable computers, the computing device generally includes a processor, a storage medium readable by the processor (including volatile and non-volatile memory and/or storage elements), at least one input device, and at least one output device. One or more programs may implement or utilize the processes described in connection with the presently disclosed subject matter, e.g., through the use of an application programming interface (API), reusable controls, or the like. Such programs may be implemented in a high-level procedural or object-oriented programming language to communicate with a computer system. However, the program(s) can be implemented in assembly or machine language, if desired. In any case, the language may be a compiled or interpreted language, and it may be combined with hardware implementations.

### DISCUSSION

The accurate characterization of loss tangent is a necessary prerequisite for the work of designers of radomes, antennas, and metasurfaces, and the drive for high-efficiency, broadband microwave components informs the need for new techniques for measuring dielectric loss at microwave frequencies and above.

Existing techniques for extracting complex permittivity from microwave measurements typically fall into two distinct classifications: resonant methods and transmission/reflection methods [1]. Transmission/reflection methods propagate energy through a material under test (MUT) by placing the sample inside some transmission line as in coaxial airline [2] and rectangular waveguide [3] techniques, or by placing it along the propagation path of a wave in free space, as in the focused beam system [4].

Transmission line-based measurement methods tend to be broadband, where the bandwidth limitation arises due to higher-order propagating modes or limitations in hardware. Broadband transmission line methods suffer from poor sensitivity to loss tangent, however.

Resonant methods, unlike transmission line methods, generate high-Q resonances in the frequency domain, which increase the interaction time of injected electromagnetic energy with the material under test. Measurement methods at microwave frequencies include the split-cylinder resonator [5], the TE01n cavity [6], and the open-boundary Fabry-Perot Resonator [7], among others. These methods are sensitive to low levels of dielectric loss because the loss tangent determines the rate of energy decay in the resonance.

A frequency selective surface (FSS) is a resonant structure, a spatial filter with a particular frequency response determined by a two-dimensional periodic surface [8]. It is often convenient to represent the frequency response of an FSS by its lumped circuit equivalence, as shown in FIG. 5F, making it readily apparent that the resonant behavior of the FSS is highly dependent on the materials making up the components. As with the dielectric between two plates in a capacitor, the dielectric through which the fringing electric field between traces on the FSS appear determines the effective capacitance of the circuit. Considering a hypothetical FSS consisting of metallic sheets on a plane in free space with resonant frequency f0, if it were to be immersed in an infinitely thick dielectric with relative permittivity r, one would find this new FSS to have a new resonant frequency of:

$${f}_{1} = \frac{{f}_{0}}{\sqrt{{∈}_{r}}} .$$

The FSS is embedded in a dielectric substrate of finite thickness, so the resonant frequency of an FSS on a dielectric substrate typically lands somewhere between the “suspended in free space” resonance at f₀ and the “embedded in infinitely thick dielectric” resonance at f₀/\sqrt{ϵᵣ}. In practice, a dielectric thickness of >λ/20 on both sides of the periodic surface is sufficient to converge to the lower limit [8].

One of the instant studies introduced the loss tangent measurement surface (LTMS), which is a measurement fixture and technique for measuring the complex relative permittivity of dielectric substrates by taking advantage of resonance shifts induced by materials in close proximity to an FSS. This technique hybridized the two classes of measurement techniques discussed above in that expensive measurement hardware remains broadband in nature, while an inexpensive and easily interchangeable FSS is used to create a resonant response at a particular spot frequency. The use of FSS like structures as resonant filters to measure dielectric properties has been reported in [9]-[12], but their use is confined to waveguides of limited bandwidth potential.

Instead of placing a sample in a resonant cavity, the exemplary system uses a resonate surface and puts that on the material, and uses standard measurement techniques in some embodiment. This has not been done in a free-space method before. The technique is nondestructive, broadband, and cheaper to implement. The prior system did use resonance structures generally, but not the way that the exemplary system uses them by taking advantage of a periodic measurement resonance surface. Prior wave resonance structures need to model the entire structure, which is expensive and takes time. There is also no expectation that there would be an analytic solution for that prior structure. With the exemplary system, some analytic solutions can be determined.

Many people in aerospace use free space systems. This system can be configured as an augmentation kit that is electronically reconfigurable. Instead of having several masks to get the bandwidth of interest, a single mask may be used with integrated active electronics that allow the frequency to be tuned with some electronic bias.

In other systems, the use of a waveguide as the source of incident electromagnetic energy may greatly limit the bandwidth of the measurement technique. The limited periodicity of the structures in the prior art makes the design of the structure and simulation thereof significantly more challenging and time-consuming, as the entire structure must be modeled instead of a single unit cell of the periodic array. The following methods require various different sizes of samples depending on the frequency of interest.
X.-C. Zhu, W. Hong, K. Wu, H.-J. Tang, Z.-C. Hao, and H.-X. Zhou, “Characterization of substrate material using complementary split ring resonators at terahertz frequencies,” in 2013 IEEE International Wireless Symposium (IWS), 2013, pp. 1-4. doi: 10.1109/IEEE-IWS.2013.6616829.
F. Costa, M. Degiorgi, M. Borgese, A. Monorchio, and G. Manara, “Permittivity measurement of thin dielectrics by using metamaterial absorbers inside a waveguide,” in 2017 IEEE International Symposium on Antennas and Propagation &USNC/URSI National Radio Science Meeting, 2017, pp. 889-890. doi: 10.1109/APUSNCURSINRSM.2017.8072487.
F. S. Jafari and J. Ahmadi-Shokouh, “Frequency-Selective Surface to Determine Permittivity of Industrial Oil and Effect of Nanoparticle Addition in X-Band,” Journal of Electronic Materials, vol. 47, no. 2, pp. 1397-1404, 2018, doi: 10.1007/s11664-017-5944-4.
F. Bagci, M. S. Gulsu, and B. Akaoglu, “Dual-band measurement of complex permittivity in a microwave waveguide with a flexible, thin and sensitive metamaterial-based sensor,” Sensors and Actuators A: Physical, vol. 338, p. 113480, May 2022, doi: 10.1016/j.sna.2022.113480.

Computer-executable instructions, such as program modules, being executed by a computer may be used. Generally, program modules include routines, programs, objects, components, data structures, etc., that perform particular tasks or implement particular abstract data types. In its most basic configuration, the controller includes at least one processing unit and memory. Depending on the exact configuration and type of computing device, memory may be volatile (such as random-access memory (RAM)), non-volatile (such as read-only memory (ROM), flash memory, etc.), or some combination of the two. The controller of FIG. 10 may have additional features/functionality. For example, the computing device may include additional storage (removable and/or non-removable) including, but not limited to, magnetic or optical disks or tape. Such additional storage may include removable storage and/or non-removable storage.

It should be understood that the various techniques described herein may be implemented in connection with hardware components or software components or, where appropriate, with a combination of both. Illustrative types of hardware components that can be used include Field-programmable Gate Arrays (FPGAs), Application-specific Integrated Circuits (ASICs), Application-specific Standard Products (ASSPs), System-on-a-chip systems (SOCs), Complex Programmable Logic Devices (CPLDs), etc. The methods and apparatus of the presently disclosed subject matter, or certain aspects or portions thereof, may take the form of program code (i.e., instructions) embodied in tangible media, such as floppy diskettes, CD-ROMs, hard drives, or any other machine-readable storage medium where, when the program code is loaded into and executed by a machine, such as a computer, the machine becomes an apparatus for practicing the presently disclosed subject matter.

Although exemplary implementations may refer to utilizing aspects of the presently disclosed subject matter in the context of one or more stand-alone computer systems, the subject matter is not so limited but rather may be implemented in connection with any computing environment, such as a network or distributed computing environment. Still further, aspects of the presently disclosed subject matter may be implemented in or across a plurality of processing chips or devices, and storage may similarly be implemented across a plurality of devices. Such devices might include personal computers, network servers, handheld devices, and wearable devices, for example.

Although example embodiments of the present disclosure are explained in some instances in detail herein, it is to be understood that other embodiments are contemplated. Accordingly, it is not intended that the present disclosure be limited in its scope to the details of construction and arrangement of components set forth in the following description or illustrated in the drawings. The present disclosure is capable of other embodiments and of being practiced or carried out in various ways.

It must also be noted that, as used in the specification and the appended claims, the singular forms “a,” “an,” and “the” include plural referents unless the context clearly dictates otherwise. Ranges may be expressed herein as from “about” or “5 approximately” one particular value and/or to “about” or “approximately” another particular value. When such a range is expressed, other exemplary embodiments include from the one particular value and/or to the other particular value.

By “comprising” or “containing” or “including” is meant that at least the name compound, element, particle, or method step is present in the composition or article or method, but does not exclude the presence of other compounds, materials, particles, method steps, even if the other such compounds, material, particles, method steps have the same function as what is named.

In describing example embodiments, terminology will be resorted to for the sake of clarity. It is intended that each term contemplates its broadest meaning as understood by those skilled in the art and includes all technical equivalents that operate in a similar manner to accomplish a similar purpose. It is also to be understood that the mention of one or more steps of a method does not preclude the presence of additional method steps or intervening method steps between those steps expressly identified. Steps of a method may be performed in a different order than those described herein without departing from the scope of the present disclosure. Similarly, it is also to be understood that the mention of one or more components in a device or system does not preclude the presence of additional components or intervening components between those components expressly identified.

The term “about,” as used herein, means approximately, in the region of, roughly, or around. When the term “about” is used in conjunction with a numerical range, it modifies that range by extending the boundaries above and below the numerical values set forth. In general, the term “about” is used herein to modify a numerical value above and below the stated value by a variance of 10%. In one aspect, the term “about” means plus or minus 10% of the numerical value of the number with which it is being used. Therefore, about 50% means in the range of 45%-55%. Numerical ranges recited herein by endpoints include all numbers and fractions subsumed within that range (e.g., 1 to 5 includes 1, 1.5, 2, 2.75, 3, 3.90, 4, 4.24, and 5).

Similarly, numerical ranges recited herein by endpoints include subranges subsumed within that range (e.g., 1 to 5 includes 1-1.5, 1.5-2, 2-2.75, 2.75-3, 3-3.90, 3.90-4, 4-4.24, 4.24-5, 2-5, 3-5, 1-4, and 2-4). It is also to be understood that all numbers and fractions thereof are presumed to be modified by the term “about.”

The following patents, applications and publications as listed below and throughout this document are hereby incorporated by reference in their entirety herein.

### REFERENCE LIST #1

[1] K. Y. You, F. B. Esa, and Z. Abbas, “Macroscopic characterization of materials using microwave measurement methods A survey,” in 2017 Progress in Electromagnetics Research Symposium—Fall (PIERS-FALL), 2017, pp. 194-204. doi: 10.1109/PIERS-FALL.2017.8293135.
[2] C. A. Jones, J. H. Grosvenor, and C. M. Weil, “RF material characterization using a large-diameter (76.8 mm) coaxial air line,” in 13th International Conference on Microwaves, Radar and Wireless Communications. MIKON—2000. Conference Proceedings (IEEE Cat. No. 00EX428), 2000, vol. 2, pp. 417-420. doi: 10.1109/MIKON.2000.913959.
[3] J. Baker-Jarvis, Transmission/reflection and short circuit line permittivity measurements. Boulder, CO: National Institute of Standards and Technology, 1990.
[4] D. R. Reid and G. S. Smith, “Design and optimization of Fresnel zone plates using a genetic algorithm and a full-electromagnetic simulator,” Microwave and Optical Technology Letters, vol. 51, no. 9, pp. 2223-2227, 2009, doi: 10.1002/mop.24520.
[5] J. Krupka, R. N. Clarke, O. C. Rochard, and A. P. Gregory, “Split post dielectric resonator technique for precise measurements of laminar dielectric specimens-measurement uncertainties,” in 13th International Conference on Microwaves, Radar and Wireless Communications. MIKON—2000. Conference Proceedings (IEEE Cat. No. 00EX428), May 2000, vol. 1, pp. 305-308 vol. 1. doi: 10.1109/MIKON.2000.913930.
[6] J. Krupka, K. Derzakowski, B. Riddle, and J. Baker-Jarvis, “A dielectric resonator for measurements of complex permittivity of low loss dielectric materials as a function of temperature,” Measurement Science and Technology, vol. 9, no. 10, p. 7, 1998.
[7] A. C. Lynch and R. N. Clarke, “Open resonators: Improvement of confidence in measurement of loss,” IEE Proceedings A (Science, Measurement and Technology), vol. 139, no. 5, pp. 221-225, 1992, doi: 10.1049/ip-a-3.1992.0037.
[8] B. Munk, Frequency selective surfaces: Theory and design. New York: John Wiley, 2000.
[9] X.-C. Zhu, W. Hong, K. Wu, H.-J. Tang, Z.-C. Hao, and H.-X. Zhou, “Characterization of substrate material using complementary split ring resonators at terahertz frequencies,” in 2013 IEEE International Wireless Symposium (IWS), 2013, pp. 1-4. doi: 10.1109/IEEE-IWS.2013.6616829.
[10] F. Costa, M. Degiorgi, M. Borgese, A. Monorchio, and G. Manara, “Permittivity measurement of thin dielectrics by using metamaterial absorbers inside a waveguide,” in 2017 IEEE International Symposium on Antennas and Propagation & USNC/URSI National Radio Science Meeting, 2017, pp. 889-890. doi: 10.1109/APUSNCURSINRSM.2017.8072487.
[11] F. S. Jafari and J. Ahmadi-Shokouh, “Frequency-Selective Surface to Determine Permittivity of Industrial Oil and Effect of Nanoparticle Addition in X-Band,” Journal of Electronic Materials, vol. 47, no. 2, pp. 1397-1404, 2018, doi: 10.1007/s11664-017-5944-4.
[12] F. Bagci, M. S. Gulsu, and B. Akaoglu, “Dualband measurement of complex permittivity in a microwave waveguide with a flexible, thin and sensitive metamaterial-based sensor,” Sensors and Actuators A: Physical, vol. 338, p. 113480, May 2022, doi: 10.1016/j.sna.2022.113480.
[13] A. Giacomini, A. Potenza, R. Morbidini, and L. Foged, “Quad-ridge dual polarized antenna for use in the 2-32 GHz band,” in 2012 6th European Conference on Antennas and Propagation (EUCAP), 2012, pp. 769-772. doi: 10.1109/EuCAP.2012.6206229.
[14] P. G. Bartley and S. B. Begley, “Improved Free-Space S-Parameter Calibration,” in 2005 IEEE Instrumentationand Measurement Technology Conference Proceedings, May 2005, vol. 1, pp. 372-375. doi: 10.1109/IMTC.2005.1604138.

### REFERENCE LIST #2

[1′] Howard, C. T., Allen, K. W. & Hunt, W. D. A Loss Tangent Measurement Surface for Free Space Focused Beam Characterization of Low-Loss Dielectrics. In 2022 Antenna Measurement Techniques Association Symposium (AMTA), 1-6, DOI: 10.23919/AMTA55213.2022.9954958 (2022).
[2′] Klein, O., Donovan, S., Dressel, M. & Gruner, G. Microwave cavity perturbation technique: Part I: Principles. Int. J. Infrared Millim. Waves 14, 2423-2457, DOI: 10.1007/BF02086216 (1993).
[3′] Costa, F., Degiorgi, M., Borgese, M., Monorchio, A. & Manara, G. “Permittivity measurement of thin dielectrics by using metamaterial absorbers inside a waveguide. In 2017 IEEE International Symposium on Antennas and Propagation & USNC/URSI National Radio Science Meeting, 889-890, DOI: 10.1109/APUSNCURSINRSM.2017.8072487 (2017).
[4′] Jafari, F. S. & Ahmadi-Shokouh, J. Frequency-Selective Surface to Determine Permittivity of Industrial Oil and Effect of Nanoparticle Addition in X-Band. J. Electron. Mater. 47, 1397-1404, DOI: 10.1007/s11664-017-5944-4 (2018).
[5′] Bagci, F., Gulsu, M. S. & Akaoglu, B. Dual-band measurement of complex permittivity in a microwave waveguide with a flexible, thin and sensitive metamaterial-based sensor. Sensors Actuators A: Phys. 338, 113480, DOI: 10.1016/j.sna.2022. 113480 (2022).
[6′] Guglielmi, M. & Oliner, A. Multimode network description of a planar periodic metal-strip grating at a dielectric interface. I. Rigorous network formulations. IEEE Transactions on Microw. Theory Tech. 37, 534-541, DOI: 10.1109/22.21625 (1989).
[7′] Pasdari-Kia, M., Memarian, M. & Khavasi, A. Generalized equivalent circuit model for analysis of graphene/metal-based plasmonic metasurfaces using Floquet expansion. Opt. Express 30, 35486, DOI: 10.1364/OE.471558 (2022).
[8′] C. T. Howard, K. W. Allen, and W. D. Hunt, “A Loss Tangent Measurement Surface for Free Space Focused Beam Characterization of Low-Loss Dielectrics,” in 2022 Antenna Measurement Techniques Association Symposium (AMTA), October 2022, pp. 1-6. doi: 10.23919/AMTA55213.2022.9954958.
[9′] F. Homer, T. A. Taylor, R. Dunsmuir, J. Lamb, and W. Jackson, “Resonance methods of dielectric measurement at centimetre wavelengths,” J. Inst. Electr. Eng.—Part III Radio Commun. Eng., vol. 93, no. 21, pp. 53-68, January 1946, doi: 10.1049/ji-3-2.1946.0010
[10′] A. P. Gregory, “Q-factor measurement by using a Vector Network Analyser,” National Physical Laboratory, January 2022. doi: 10.47120/npl.MAT58.
[11′] W. L. Ko and R. Mittra, “A combination of FD-TD and Prony's methods for analyzing microwave integrated circuits,” IEEE Trans. Microw. Theory Tech., vol. 39, no. 12, pp. 2176-2181, December 1991, doi: 10.1109/22.106561.
[12′] F. Costa, A. Monorchio, and G. Manara, “An Overview of Equivalent Circuit Modeling Techniques of Frequency Selective Surfaces and Metasurfaces,” Appl. Comput. Electromagn. Soc. J. ACES, pp. 960-976, 2014.
[13′] S. Monni, G. Gerini, A. Neto, and A. G. Tijhuis, “Multimode Equivalent Networks for the Design and Analysis of Frequency Selective Surfaces,” IEEE Trans. Antennas Propag., vol. 55, no. 10, pp. 2824-2835, October 2007, doi: 10.1109/TAP.2007.905846.
[14′] T. Cwik and R. Mittra, “The cascade connection of planar periodic surfaces and lossy dielectric layers to form an arbitrary periodic screen,” IEEE Trans. Antennas Propag., vol. 35, no. 12, pp. 1397-1405, December 1987, doi: 10.1109/TAP.1987.1144054.
[15′] S. Agahi and R. Mittra, “Design of a cascaded frequency selective surface as a dichroic subreflector,” in International Symposium on Antennas and Propagation Society, Merging Technologiesfor the 90's, May 1990, pp. 88-91 vol. 1. doi: 10.1109/APS.1990.115055.
[16′] F. Costa, M. Borgese, M. Degiorgi, and A. Monorchio, “Electromagnetic Characterisation of Materials by Using Transmission/Reflection (T/R) Devices,” Electronics, vol. 6, no. 4, p. 95, 2017, doi: 10.3390/electronics6040095.
[17′] S. K. Sharma, A. Lüttgen, and C. D. Sarris, “An Optimization Driven Approach for Designing Touch Sensor Panels for Integration With Antennas,” IEEE Sensors Journal, vol. 21, no. 18, pp. 20192-20199, 2021, doi: 10.1109/JSEN.2021.3096746.
[18′] K. W. Allen, D. J. P. Dykes, D. R. Reid, and R. T. Lee, “Multi-Objective Genetic Algorithm Optimization of Frequency Selective Metasurfaces to Engineer Ku-Passband Filter Responses.” Progress In Electromagnetics Research, vol. 167, pp. 19-30, 2020, doi: 10.2528/PIER19112609.
[19′] “RT/Duroid® 5870/5880 High Frequency Laminates Data Sheet,” Rogers Corporation, Chandler, Az, #92-101, 2022.
[20′] K. W. Allen, M. M. Scott, D. R. Reid, J. A. Bean, J. D. Ellis, A. P. Morris, and J. M. Marsh, “An X-band waveguide measurement technique for the accurate characterization of materials with low dielectric loss permittivity,” Review of Scientific Instruments, vol. 87, no. 5, p. 054703, May 2016.
[21′] Y. Zhang, E. Li, G. Guo, J. Xu, and C. Wang, “An estimate of the error caused by the elongation of the wavelength in a focused beam in freespace electromagnetic parameters measurement,” Review of Scientific Instruments, vol. 85, no. 9, p. 094702, September 2014.
[22′] K. Y. You, F. B. Esa, and Z. Abbas, “Macroscopic characterization of materials using microwave measurement methods—A survey,” in 2017 Progress in Electromagnetics Research Symposium—Fall (PIERS-FALL), November 2017, pp. 194-204.
[23′] J. P. Turpin, J. A. Bossard, K. L. Morgan, D. H. Werner, and P. L. Werner, “Reconfigurable and Tunable Metamaterials: A Review of the Theory and Applications,” International Journal of Antennas and Propagation, vol. 2014, p. 429837, May 2014.
[24′] C. Li, C. Wu, and L. Shen, “Complex Permittivity Measurement of Low-Loss Anisotropic Dielectric Materials at Hundreds of Megahertz,” Electronics, vol. 11, no. 11, p. 1769, January 2022.
[25′] M. Capek, L. Jelinek, and P. Hazdra, “On the Functional Relation Between Quality Factor and Fractional Bandwidth,” IEEE Transactions on Antennas and Propagation, vol. 63, no. 6, pp. 2787-2790, June 2015.
[26′] G. Xu, S. V. Hum, and G. V. Eleftheriades, “A Technique for Designing Multilayer Multistopband Frequency Selective Surfaces,” IEEE Transactions on Antennas and Propagation, vol. 66, no. 2, pp. 780-789, February 2018.
[27′] O. F. Hikmat and M. S. Mohamed Ali, “RF MEMS Inductors and Their Applications—A Review,” Journal of Microelectromechanical Systems, vol. 26, no. 1, pp. 17-44, February 2017.
[28′] R. G. Silva, T. M. N. Verastegui, B. Leite, and A. Mariano, “A 4.12 GHz, 3.3 mW VCO with 87.9% tuning range using a transformer-based variable inductance,” AEU—International Journal of Electronics and Communications, vol. 163, p. 154595, May 2023.
[29′] S. K. Azam, M. I. Ibrahimy, S. Motakabber, and A. Z. Hossain, “Plans for Planar: Phase-Noise Reduction Techniques in Voltage-Controlled Oscillators,” IEEE Microwave Magazine, vol. 20, no. 11, pp. 92-108, November 2019.
[30′] J. Mou and Z. Shen, “Broadband and thin magnetic absorber with non-Foster metasurface for admittance matching,” Scientific Reports, vol. 7, no. 1, p. 6922, July 2017.
[31′] A. V. Rudyk, A. O. Semenov, N. Kryvinska, and O. O. Semenova, “Measuring quality factors of the radio-frequency system components using equivalent circuits,” Journal of Computational Electronics, vol. 20, no. 5, pp. 1977-1991, October 2021.
[32′] MACOM Technology Solutions Inc., “MAVR-011020-1411: Solderable GaAs Constant Gamma Flip-Chip Varactor Diode.” [Online]. Available: https://cdn.macom.com/datasheets/MAVR-011020-1141.pdf
[33′] K. Deb, A. Pratap, S. Agarwal, and T. Meyarivan, “A fast and elitist multiobjective genetic algorithm: NSGA-II,” IEEE Transactions on Evolutionary Computation, vol. 6, no. 2, pp. 182-197, 2002.
[34′] M. Piket-May, W. Gwarek, T.-L. Wu, B. Houshmand, T. Itoh, and J. Simpson, “High-Speed Electronic Circuits with Active and Nonlinear Components,” in Computational Electrodynamics: The Finite-Difference Time-Domain Method. Norwood, MA: Artech House, 2005, pp. 677-742.
[35′] A. P. Gregory, “Q-factor measurement by using a Vector Network Analyser,” National Physical Laboratory, 2022. doi: 10.47120/npl.MAT58.

What is claimed is:

1. A method to perform material or device electromagnetic characterization, the method comprising:
providing a dielectric test material of interest;
providing a conductive substrate or elements with a periodic pattern or metasurface in proximity to the dielectric test material to form a test assembly, wherein the conductive substrate or elements are configured to transmit or reflect electromagnetic energy incident upon it with a resonant response with center frequency and resonance shape that varies based on permittivity properties of the dielectric test material;
directing electromagnetic energy to the test assembly, wherein the directed electromagnetic energy causes interactions between (i) the periodic pattern or metasurface of the conductive substrate or elements, and (ii) the dielectric test material;
capturing an electromagnetic energy profile of the test assembly; and
determining an electromagnetic property of the test assembly based on the captured electromagnetic energy profile, wherein the electromagnetic property of the test assembly is used as a characterization of the dielectric test material.

2. The method of claim 1, wherein the conductive substrate or elements are formed on a carrier dielectric substrate that is attached to the dielectric test material to form the test assembly.

3. The method of claim 1, wherein the conductive substrate or elements include an active electronic circuitry that is placed upon or embedded in a layer of the conductive substrate or elements, and wherein electronic vias are formed between the active electronic circuitry and the conductive substrate or elements.

4. The method of claim 3, wherein the active electronic circuitry is configured to adjust resonant properties of the conductive substrate or elements.

5. The method of claim 4, wherein the electromagnetic energy is directed by an antenna, a focused beam, a coaxial airline, a waveguide, or a combination thereof.

6. The method of claim 1, wherein the conductive substrate or elements comprise the periodic pattern, and wherein a periodicity between elements in the periodic pattern is between 50% and 80% of a wavelength at the resonant frequency of an interrogation signal corresponding to the directed electromagnetic energy.

7. The method of claim 1, further comprising:
evacuating air between the dielectric test material and the conductive substrate or elements.

8. The method of claim 1, further comprising:
providing a second conductive substrate or elements with a second periodic pattern or metasurface in proximity to the dielectric test material to form a second test assembly;
directing electromagnetic energy to the second test assembly, wherein the directed electromagnetic energy causes interactions between (i) the second periodic pattern or metasurface of the conductive substrate or elements, and (ii) the dielectric test material; and
capturing a second electromagnetic energy profile of the second test assembly, wherein the captured second electromagnetic energy profile, or a parameter derived therefrom, of the second test assembly is used as another characterization of the dielectric test material.

9. A system comprising:
a test assembly including a conductive periodic pattern or metasurface and a dielectric test material, wherein the conductive substrate or elements are placed in contact with or in proximity to the dielectric test material, and wherein the conductive substrate or elements are configured to transmit or reflect electromagnetic energy incident upon it with a resonant response with center frequency and resonance shape that varies based on permittivity properties of the dielectric test material;
an antenna configured to capture an electromagnetic energy profile of the test assembly in response to electromagnetic energy directed to the test assembly, wherein the directed electromagnetic energy causes interactions between (i) the periodic pattern or metasurface of the conductive substrate or elements, and (ii) the dielectric test material; and
an analyzer configured to measure and determine an electromagnetic property of the test assembly based on the captured electromagnetic energy profile, wherein the electromagnetic property of the test assembly is used as a characterization of the dielectric test material.

10. The system of claim 9, wherein the analyzer is further configured to:
determine dielectric constant and loss tangent of the dielectric test material.

11. The system of claim 10, wherein the conductive substrate or elements are formed on a dielectric substrate that is attached to the dielectric test material to form the test assembly.

12. The system of claim 10, wherein the test assembly includes active electronic circuitry that is placed upon or embedded in a layer of the dielectric substrate, and wherein electronic vias are formed between the active electronic circuitry and the conductive substrate or elements.

13. The system of claim 12, wherein the active electronic circuitry is configured to adjust resonant properties of the conductive substrate or elements.

14. The system of claim 9 further comprising an energy generator configured to generate and/or direct the electromagnetic energy.

15. The system of claim 14, wherein the energy generator comprises a microwave source, power meters, network analyzer, antennas, focusing lenses or reflectors, a coaxial airline, a waveguide, or a combination thereof.

16. The system of claim 9, wherein the conductive substrate or elements comprise the periodic pattern, and wherein a periodicity between elements in the periodic pattern is between 50% and 80% of a wavelength at the resonant frequency of an interrogation signal corresponding to the directed electromagnetic energy.

17. The system of claim 9, wherein the system is configured as a broadband-focused beam system.

18. The system of claim 9, wherein the test assembly is mounted on a fixture.

19. The system of claim 9, wherein the test assembly is mounted on a vacuumed fixture comprising vacuum channels, fittings, and integrated seals.

20. A non-transitory computer readable medium comprising a memory having instructions stored thereon to cause a processor to:
analyze an electromagnetic energy profile acquired via a test assembly in response to electromagnetic energy directed thereto, wherein the test assembly includes (i) a conductive layer with a periodic pattern or metasurface and (ii) a dielectric test material, wherein the conductive layer is in contact with or positioned in proximity to the dielectric test material, wherein the conductive layer is configured to transmit or reflect electromagnetic energy incident upon it with a resonant response with center frequency and resonance shape that varies based on permittivity properties of the dielectric test material, and wherein the directed electromagnetic energy causes interactions between (i) the periodic pattern or metasurface of the conductive layer, and (ii) the dielectric test material.
